(19) United States
(12) Patent Application Publication
(10) Pub. No.: US 2025/0282623 A1
(43) Pub. Date: Sep. 11, 2025

(54) SYSTEMS AND METHODS FOR PRODUCING GRAPHENE

(71) Applicant: Universal Matter Inc., Burlington (CA)

(72) Inventors: Vladimir Mancevski, Austin, TX (US); Duy Xuan Luong, Houston, TX (US); Tyler Cooksey, Houston, TX (US); John Williams, Gonzales, TX (US); Eytan Mazor, Oakville (CA); Zhiyong Zhang, Katy, TX (US); Benny Jay, Austin, TX (US)

(21) Appl. No.: 18/694,308

(22) PCT Filed: Sep. 21, 2022
(86) PCT No.: PCT/CA2022/051406

§ 371 Date: Mar. 21, 2024

Related U.S. Application Data
(60) Provisional application No. 63/246,424, filed on Sep. 21, 2021.

(51) Int. Cl. C01B 32/184; B01J 6/00

(52) U.S. Cl. CPC C01B 32/184; B01J 6/008

(57) ABSTRACT

Provided is a device, method, and material for converting a feedstock to a resultant material having a higher degree of crystallinity than the feedstock. The device includes a constraining reservoir configured to constrain the feedstock which forms a resistive electrical load and comprise a mass of at least. 1 kg. The device further includes electrodes configured to transmit an electrical current through the feedstock to joule heat the feedstock; a compression system configured to compress the feedstock to adjust feedstock electrical resistance; and an alternating current (AC) power source electrically connected to the electrodes. The device further includes an electric controller to control an electric current delivered to the feedstock. The method further includes filing the constraining reservoir with the feedstock, compressing the feedstock, electronically connecting the feedstock to the AC power source, and applying the electrical power to the resistive load until a limit is reached.

### TECHNICAL FIELD

The embodiments disclosed herein relate to producing graphene, and, in particular, to systems and methods for industrial scale graphene production.

### Introduction

The details of making graphene with flash joule heating has been disclosed in a Nature publication (Luong, D. X., Bets, K. V., Algozeeb, W. A., Stanford, M. G., Kittrell, C., Chen, W., Salvatierra, R. V., Ren, M., McHugh, E. A., Advincula, P. A. and Wang, Z., 2020. Gram-scale bottom-up flash graphene synthesis. Nature, 577(7792), pp. 647-651) and followed up with additional disclosures that focus on plastic-based feedstock (Wala A. Algozeeb, Paul E. Savas, Duy Xuan Luong, Weiyin Chen, Carter Kittrell, Mahesh Bhat, Rouzbeh Shahsavari, and James M. Tour, Flash Graphene from Plastic Waste, ACS Nano 2020, 14, 11, 15595-15604, Publication Date: Oct. 29, 2020, https://doi.org/10.1021/acsnano.0c06328) and rubber-based feedstock (Paul A. Advincula, Duy Xuan Luong, Weiyin Chen, Shivaranjan Raghuraman, Rouzbeh Shahsavari, James M. Tour, Flash graphene from rubber waste, Carbon, Volume 178, 2021, Pages 649-656, ISSN 0008-6223, https://doi.org/10.1016/j.carbon.2021.03.020). The apparatus and process disclosed in the these references are limited to flashing 1 g of carbon-based feedstock that is converted to turbostratic graphene (TG) with the help of electrically induced flash joule heating with short duration voltage pulses (thus the flash aspect of the process) that only lasts milliseconds to 5 seconds (James Tour et al., FLASH JOULE HEATING SYNTHESIS METHOD AND COMPOSITIONS THEREOF, WO 2020/051000 A1, filed Aug. 23, 2019 with priority date of Sep. 5, 2018).

The electrical power required for the joule heating in these methods are direct current (DC) electrical power provided by a capacitor bank, and in some cases AC power is used to preheat the sample followed by DC power to convert the carbon feedstock into TG. The AC voltage used in these methods for preheating of up to 1 gram carbon-based feedstock was 120 Volts AC (VAC).

Other relevant introductory materials includes the disclosure describing device, method and carbon-based pill joule flash flashing (Vladimir Mancevski, DEVICE, METHOD, AND CARBON PILL FOR SYNTHESIZING GRAPHENE, PCT/CA2020/051368, filed Oct. 13, 2020 and with priority date of Oct. 11, 2019) which is herby incorporated as reference, and a disclosure describing device and methods for continuous synthesis of graphene by flash joule heating (Vladimir Mancevski, DEVICE AND METHOD FOR CONTINUOUS SYNTHESIS OF GRAPHENE, PCT/CA2020/051565, filed Nov. 17, 2020 and with priority date of Nov. 17, 2019) which is herby incorporated as reference.

Accordingly, there is a need for improved graphite production systems and methods using joule heating on an industrial scale.

### SUMMARY

Provided is a device for conversion of at least one feedstock to a resultant material. The resultant material has a higher degree of crystallinity than the feedstock. The device includes a constraining reservoir configured to constrain the feedstock. The feedstock acts as a resistive electrical load and comprises a mass of at least 0.1 Kg. The device further includes a plurality of electrodes configured to transmit an electrical current through the feedstock to joule heat the feedstock. The device further includes a compression system configured to compress the feedstock with a compression force to adjust feedstock electrical resistance. The device further includes an alternating current (AC) power source for providing AC electrical current to the electrodes. The device further includes at least one electrical controller configured to control the electrical current delivered to the feedstock.

The feedstock may include carbon and the resultant material may include graphene.

The conversion of the feedstock may result in one or more of graphene, 1 D and 2D carbon, single walled carbon nanotubes, multiwalled carbon nanotubes, carbon nanoribbons, molybdenum disulfide, tungsten disulfide, boron nitride, borocarbonitride, fluorinated nanodiamond, fluorinated turbostratic graphene, fluorinated concentric carbon, heteroatom-doped graphene, titanium carbide, zirconium carbide, molybdenum carbide, tungsten carbide, boron carbide, silicon carbide, niobium carbide, rhodium, palladium, silver, gold, cobalt, rare earth elements, corundum nanoparticles, graphite anode battery materials, and cathode battery materials.

The electrode may further be configured to constrain the feedstock.

The AC power source may be one or more of a grid power supply, and an industrial generator.

The AC power source may be one or more of pure and rectified.

The feedstock may include one or more of carbon derived from hydrogen production process that includes the production of turquoise hydrogen from methane, metallurgical coke, anthracite coal, green petroleum coke, calcinated petroleum coke, recycled-tire carbon black, carbon black, char, bio char, wood char, plant char, ground coffee, coffee char, plastic, plastic char, plastic ash, polypropylene, polyethylene, polyurethane, and Styrofoam.

The feedstock may further include at least one secondary material wherein the secondary material is one or more of sacrificial, a catalyst, or a reactant.

The secondary material may include one or more of water, ground coffee, corn starch, pine bark, polyethylene microwax, wax, chemplex 690, cellulose, naptenic oil, asphaltenes, gilsonite, water, Carboxy Methyl Cellulose (CMC), lignan, lignin, sodium lignosulfonate, calcium lignosulfonate, developmental sodium lignin, desugared calcium lignosulfonate, ammonium lignon sulfonate, calcium lignin, brewers condensed solubles, de-sugarized beet molasses, calcinated petroleum coke, tire carbon black, carbon black, metallurgical coke, turbostratic graphene, and carbon nanotubes, Fe, Cu, Al, transition group metals, main group metals, TiO2, Al2O3, SiO2, oxides, NaCl, KCl, MgCl2, CaCO3, CuSO4, metal salt, KOH, NaOH, bases, Pt, Pd, Ru, Au, Ir, Rh, Co, Fe, Cu, Ni, Zn, Bi, Pt(acac)2, AuCl3, AgNO3, metal precursor, TiO2, Al2O3, SiO2, iron acetate, iron chloride, iron acetylacetonate, metal salt, iron oxide, cobalt oxide, transition metal oxide, iron hydroxide, nickel hydroxide, transition metal hydroxide, silicon, silicon oxide, and SiOx-based anode material.

The constraining reservoir may be configured in one or more of a tube, a half tube, a hollow rectangular prism, a hollow half rectangular prism, a hollow hexagonal prism, and a gear.

The morphology of the feedstock may include one or more of super fine grain or powder, micro fine grain or powder, very fine grain, fine grain, coarse grain, pellets, medium chunks, chips, and MetCoke breeze, and at least one pill.

The devices may include at least one electrical switch configured to control the flow of electrical current to the plurality of electrodes.

The compression force may be left to act during the conversion.

The compression assembly may include one or more of, a spring, a clamp, a pneumatic actuator, free weight, and a compressing roll.

The compression assembly may include the electrodes. At least a portion of the compression force may be applied to the feedstock by the electrodes.

The compression force may be applied along the direction which the electrical current is applied.

The compression force may be applied perpendicular to the direction which the electrical current is applied.

The AC power source may include at least one factory transformer configured to transform the voltage of the AC power source.

The device may include a plurality of switches and resistive loads and the power lines may be configured to operate in a Wye configuration.

The device may include a plurality of switches and resistive loads and the power lines may be configured to operate in a Delta configuration.

The device may include a first switch corresponding to a first load and a second switch corresponding to a second load and the first switch and second switch are operated consecutively such that electric current is engaged only one load at a time.

The device may include a first switch corresponding to a first load and a second switch corresponding to a second load and the first switch and second switch may be operated such that electric current is engaged in first load and second load concurrently.

The device may include a first load and a second load wherein the switch is configured to pause between processing the first load and second load.

The device may include a reactive component configured to add one or more of impedance and phase offset and the reactive component may be one or more of an inductor and a capacitor.

The AC power source may provide a first joule heating phase and a second joule heating phase wherein the power applied in first joule heating phase is different from the power applied in the second joule heating phase.

The first joule heating phase may include a first batch of feedstock heated to create a second batch of feedstock and the second joule heating phase may include the second batch of feedstock.

The power may be varied by varying one or more of a current and a voltage.

The AC power source may further include one or more of a DC converter drive and a variable frequency drive for regulating the power applied by the AC power source.

The device may be configured to terminate based on one or more of a cumulative energy deposited to the feedstock, a time of running current to the feedstock, a maximum power applied to the feedstock, a feedstock resistance, a temperature, a max pressure in the constraining reservoir, a max force to the constraining reservoir, a low feedstock resistance condition, a max feedstock temperature, a max current to the feedstock, a max power to the feedstock, a max I2*t (Amp2*time) of the power lines, a max power line temperature, a max conduit temperature of a conduit, and max relay temperature of the switch.

The constraining structure may include one or more of quartz, ceramic, cement, concrete, silicon carbide, magnesium-based refractories, magnesia-carbon, dead-burned magnesite —MgO, magnesite-chrome, magnesia-alumina spinel, dolomite, dead-burned dolomite, resin bonded dolomite, aluminum-based refractories, alumina-magnesia-graphite, fireclay refractory having hydrated aluminum silicates, high alumina refractories, and phosphate bonded high alumina.

The electrodes may be configured to move along the confines of the constraining structure based on feedstock volume changes.

The constraining reservoir may further include a gas escape configured to allow gas produced during the conversion to escape the constraining reservoir and the gas escape may include at least one gap in the constraining structure, the gap comprising one or more of a gap at a first end of the containing reservoir, a gap at a second end of the containing reservoir, at least one groove of the electrodes, a longitudinal split in the containing reservoir wherein the longitudinal split divides the containing reservoir into a plurality of sections, a cross-sectional split in the containing reservoir wherein the cross sectional split divides the containing reservoir into a plurality of sections, a hole in the containing reservoir, and a gap between a first layer of the containing reservoir and a second layer of the containing reservoir.

The split may be configured with a serpentine wall interface.

The electrodes may be one or more of solid, grooved, necked, and drilled graphite electrodes.

An inner surface of the containing reservoir may be lined with refractory cement.

The constraining reservoir further may include a feedstock environment, the feedstock environment further comprising one or more of a vacuum, an oxygen saturation greater than atmosphere, and an inert gas.

The device may include at least one conveyer configured to one or more of load and unload the constraining reservoir.

Provided is a method for conversion of at least one feedstock to a resultant material. The resultant material has a higher degree of crystallinity than the feedstock. The method includes filling a constraining reservoir with the feedstock comprising a mass of at least 0.1 Kg to form a resistive load. The method further includes compressing the feedstock with a compression force to adjust feedstock electrical resistance. The method further includes electronically connecting the feedstock within the constraining reservoir to an alternating current (AC) power source. The method further includes applying the electrical power to the resistive load until a limit is reached. The limit indicates that sufficient energy and power has been applied to the feedstock by the applied electric power to convert the feedstock into the resultant material.

The constraining reservoir may include constraining structure configured to constrain the resistive load.

The method may include applying the power via an electrical switch, wherein the electrical switch regulates the AC power applied to the resistive load.

The method may include transforming the AC power source via at least one factory transformer.

The method may include operating consecutively a first switch corresponding to a first load and a second switch corresponding to a second load such that electric current is engaged only one load at a time.

The method may include operating consecutively a first switch corresponding to a first load and a second switch corresponding to a second load such that electric current is engaged in first load and second load concurrently.

The method may include operating the switch by pausing between processing a first load and a second load.

The method may include regulating the power applied by one or more of DC converter drive and a variable frequency drive for regulating the power applied by the AC power source.

The method may further include providing a feedstock environment of the constraining reservoir further by providing in the constraining reservoir one or more of a vacuum, an oxygen saturation greater than atmosphere, and an inert gas.

The method may further include loading and unloading the constraining reservoir by at least one conveyer.

The method may further include adding the resultant product to one or more of cement, concrete, polyurethane foam, plastic, nylon rubber, tire products, asphalt, epoxy and lubricant.

Provided is a material produced by conversion of at least one feedstock to a resultant material. The resultant material has a higher degree of crystallinity than the feedstock. The conversion includes filling a constraining reservoir with the feedstock comprising a mass of at least 0.1 Kg to form a resistive load. The conversion further includes compressing the feedstock via a compression force up to adjust feedstock electrical resistance. The conversion further includes electronically connecting the feedstock within the constraining reservoir to an alternating current (AC) power source. The conversion further includes applying the electrical power to the resistive load until a limit is reached, wherein the limit indicates that sufficient energy and power has been applied to the feedstock by the applied electric power to convert the feedstock into the resultant material.

The conversion may further include applying the power via an electrical switch, wherein the electrical switch regulates the AC power applied to the resistive load.

The conversion may further include transforming the AC power source via at least one factory transformer.

The conversion may further include operating consecutively a first switch corresponding to a first load and a second switch corresponding to a second load such that electric current is engaged only one load at a time.

The conversion may further include operating consecutively a first switch corresponding to a first load and a second switch corresponding to a second load such that electric current is engaged in first load and second load concurrently.

The conversion may further include operating the switch by pausing between processing a first load and a second load.

The conversion may further include varying the power applied by varying one or more of a resistance and a current of the switch.

The conversion may further include regulating the power applied by one or more of DC converter drive and a variable frequency drive for regulating the power applied by the AC power source.

The conversion may further include providing a feedstock environment of the constraining reservoir further by providing in the constraining reservoir one or more of a vacuum, an oxygen saturation greater than atmosphere, and an inert gas.

The conversion may further include loading and unloading the constraining reservoir by at least one conveyer.

The conversion may further include adding the resultant product to one or more of cement, concrete, polyurethane foam, plastic, nylon rubber, tire products, asphalt, epoxy and lubricant.

The following is intended to introduce the reader to the detailed description that follows and not to define or limit the claimed subject matter.

Other aspects and features will become apparent to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIG. 1 is a block diagram of a system for Large Scale Joule Heat Conversion of Carbon to Graphene, in accordance with an embodiment;

FIG. 2 is a flow diagram of a method for Large Scale Joule Heat Conversion of Carbon to Graphene using the system of FIG. 1, in accordance with an embodiment;

FIG. 3 is a block diagram of a System for Longitudinal Compression of Feedstock for the Large Scale Joule Heating of FIG. 1, in accordance with an embodiment;

FIG. 4 is a block diagram of System for Perpendicular Compression of Carbon-Based Feedstock for the Large Scale Joule Heating, in accordance with an embodiment;

FIG. 5 is a block diagram of a system for 3-Phase Wye Grid Power Electrical Configuration for the Large Scale Joule Heating of FIG. 1, in accordance with an embodiment;

FIG. 6 is a block diagram of a system for 3-Phase Delta Grid Power Electrical Configuration for the Large Scale Joule Heating of FIG. 1, in accordance with an embodiment;

FIG. 7 is a block diagram of an Electrical Configuration with Direct Power Plant Connection for the Large Scale Joule Heating of FIG. 1, in accordance with an embodiment;

FIG. 8 is a block diagram of a system for 3-Phase Wye Grid Power Electrical Configuration with Peak Current Limiting for the Large Scale Joule Heating of FIG. 1, in accordance with an embodiment;

FIG. 9A is a block diagram of a Joule Heating System of FIG. 1 with at Least 2 Voltages, in accordance with an embodiment;

FIG. 9B is a block diagram of a Joule Heating System of FIG. 1 with at Least 2 Voltages and with Low and High Power Transformers, in accordance with an embodiment;

FIGS. 10A and 10B are graphs of a Raman Signature of TG from Example 1, and a TGA Profile of TG from Example 1, respectively, in accordance with various embodiments;

FIGS. 11A and 11B are graphs of a Raman Signature of TG from Example 2, and a TGA Profile of TG from Example 2, respectively, in accordance with various embodiments;

FIGS. 12 and 13 are diagrams of constraining reservoirs of FIG. 1, in accordance with various embodiments;

FIG. 14 are diagrams of Electrodes of the constraining Reservoirs of FIG. 1 to Provide Process Gas Escape Capability, in accordance with an embodiment;

FIG. 15 are cross-sectional diagrams of concrete constraining reservoirs of FIG. 1, in accordance with various embodiments;

FIG. 16A is a schematic diagram of an Assembly of Concrete Constraining Reservoirs, and a Grooved Graphite Electrodes and Clamps of FIG. 1, in accordance with an embodiment;

FIG. 16B is a schematic diagram of a Concrete Tube with Steel Tube Clamp Constraining Reservoirs of FIG. 1, in accordance with an embodiment;

FIG. 17 is a perspective view of a Joule Heating Assembly of FIG. 1 with Springs and Linear Stages, in accordance with an embodiment;

FIG. 18 is a perspective view of a Joule Heating Assembly of FIG. 1 with Pneumatic Actuators, in accordance with an embodiment;

FIGS. 19A and 19B are Operational Diagrams of the Pneumatic Actuators from the Joule Heating Assembly of FIG. 1 with fixed pressure compressed air and variable pressure compressed air, respectively, in accordance with various embodiments;

FIG. 20 are diagrams of a Joule Heating Assembly of FIG. 1 with Perpendicular Electrical and Compression Directions, in accordance with an embodiment;

FIG. 21 are block diagrams of systems for large scale joule heat conversion of carbon to graphene of FIG. 1, without feedstock compression during joule heating, in accordance with an embodiment;

FIG. 22 are block diagrams of Systems for Large Scale Joule Heat Conversion of Carbon to Graphene of FIG. 1, Weighted Down and Without Feedstock Compression, in accordance with an embodiment;

FIG. 23 is a block diagram of a Half-Tube Based System for Large Scale Joule Heat Conversion of Carbon to Graphene of FIG. 1, Without Feedstock Compression, in accordance with an embodiment;

FIG. 24 are block diagrams of 3-Phase Delta Powered Systems for Large Scale Joule Heat Conversion of Carbon of FIG. 6 to Graphene Without Feedstock Compression, in accordance with an embodiment;

FIG. 25 are block diagrams of a 3-Phase Wye and Delta Powered System for Large-Scale Joule Heat Conversion of Carbon of FIG. 5, to Graphene Without Feedstock Compression, in accordance with an embodiment;

FIG. 26 are block diagram of a Coaxial Electrodes Shaped System for Large Scale Joule Heat Conversion of Carbon to Graphene of FIG. 1, Without Feedstock Compression, in accordance with an embodiment;

FIG. 27 is a block diagram of a Gear Shape System for Continuous Joule Heating Process of FIG. 2, in accordance with an embodiment;

FIG. 28 is a block diagram of a Conveyer Belt System for Continuous Joule Heating Process of FIG. 1, in accordance with an embodiment;

FIG. 29 are graphs of Compressive Strength Improvement of Concrete Composite with 0.1% TG, in accordance with an embodiment;

FIG. 30 are graphs of Compressive Strength Improvement of Concrete Composite with 0.1% TG, in accordance with an embodiment;

FIG. 31 is a block diagram of a method for Continuous Production Line for Joule Heating of FIG. 1 with 3 Phase Power, in accordance with an embodiment;

FIG. 32 is a transmission electron microscopy (TEM) image of a flake-like graphene (TG) at various resolutions, in accordance with an embodiment; and

FIG. 33 is a TEM image of a polyhedral graphene (PG) nanoparticles at various resolutions, in accordance with an embodiment.

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

Further, although process steps, method steps, algorithms or the like may be described (in the disclosure and/or in the claims) in a sequential order, such processes, methods, and algorithms may be configured to work in alternate orders. In other words, any sequence or order of steps that may be described does not necessarily indicate a requirement that the steps be performed in that order. The steps of processes described herein may be performed in any order that is practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

The term “graphene” refers to a material which is a one-atom-thick planar sheet of sp2-bonded carbon atoms that are densely packed in a honeycomb crystal lattice, and, further, contains an intact ring structure of carbon atoms and aromatic bonds throughout at least a majority of the interior sheet and lacks significant oxidation modification of the carbon atoms. Graphene has predominately crystalline structure and its quality is measured by its degree of crystallinity. Graphene is distinguishable from graphene oxide in that it has a lower degree of oxygen containing groups such as OH, COOH and epoxide. The term “a graphene monolayer” refers to graphene that is a single layer of graphene. The term “a very few layer graphene” refers to a graphene that is between 1 to 3 layers of graphene. The term “a few layer graphene” refers to a graphene that is between 2 to 5 layers of graphene. The term “a multilayer graphene” refers to a graphene that is between 2 to 10 layers of graphene.

The term “turbostratic graphene” (TG) refers to a graphene that has little order between the graphene layers. Each graphene layer of the turbostratic graphene structure is predominately crystalline in nature. Other terms which may be used include misoriented, twisted, rotated, rotationally faulted, and weakly coupled. The rotational stacking of turbostratic graphene helps mitigate interlayer coupling and increases interplanar spacing, thereby yielding superior physical properties relative to competitive graphene structures when compared on a similar weight basis. The subtle difference in adjacent layer stacking orientation expresses itself with important differences in product performance attributes. An important performance benefit evident with turbostratic graphene is that multi-layer graphene structures separate into few and individual graphene layers more easily and the graphene layers tend not to recouple. The turbostratic nature of a graphene may be observed and confirmed by Raman spectroscopy, Transmission Electron Microscopy (TEM), selected area electron diffraction (SAED), scanning transmission electron microscopy (STEM), atomic force microscopy (AFM), and X-ray diffraction (XRD) analysis.

The turbostratic graphene (TG) that is produced as a result of the joule heating process of this invention has two predominate morphologies, a flake-like turbostratic graphene structure (FTG) and polyhedral-like turbostratic graphene structure (PG), and combination of both. Typical FTG graphene ranges from 100 nm to 2 μm in lateral size and from 2 graphene layers to more than 10 layers in thickness. Polyhedral graphene is a closed form of graphene that forms a polyhedral cage, wherein multiple cages are nested within each other. Spherical cage is also possible. Typical PG graphene ranges from 20 nm to 200 nm in (diameter) size and has from 2 to more than 50 layers wall thickness. Polyhedral graphene nanoparticles can self-organize in a branched structure made from multiple PG nanoparticles, ranging in length from few nm to few microns.

The term “carbon source” generally refers to any carbon-based material typically amorphous (non-crystalline in nature) or with some degree of crystallinity, which may be converted into a predominately crystalline graphene material, preferably turbostratic graphene. The carbon source may be in any form including in a powder form, grain form, pellet form, or in a compressed pill form. The carbon source may include, without limitation, petroleum coke, tire carbon black, carbon black, metallurgical coke, plastic ash, plastic powder, ground coffee, anthracite coal, coal, corn starch, pine bark, polyethylene microwax, wax, chemplex 690, cellulose, naptenic oil, asphaltenes, gilsonite, and carbon nanotubes.

A flash joule heating synthesis method and compositions thereof are described in Patent Cooperation Treaty Application having International Publication Number WO 2020/051000 A1 to Tour et al., having an international publication date of Mar. 12, 2020, which is herein incorporated by reference in its entirety.

A method of synthesizing graphene by joule heating a carbon pill and compositions thereof are described in Patent Cooperation Treaty Application having International Application Number PCT/CA2020/051368 to Mancevski, having an international application date of Oct. 13, 2020, which is herein incorporated by reference in its entirety.

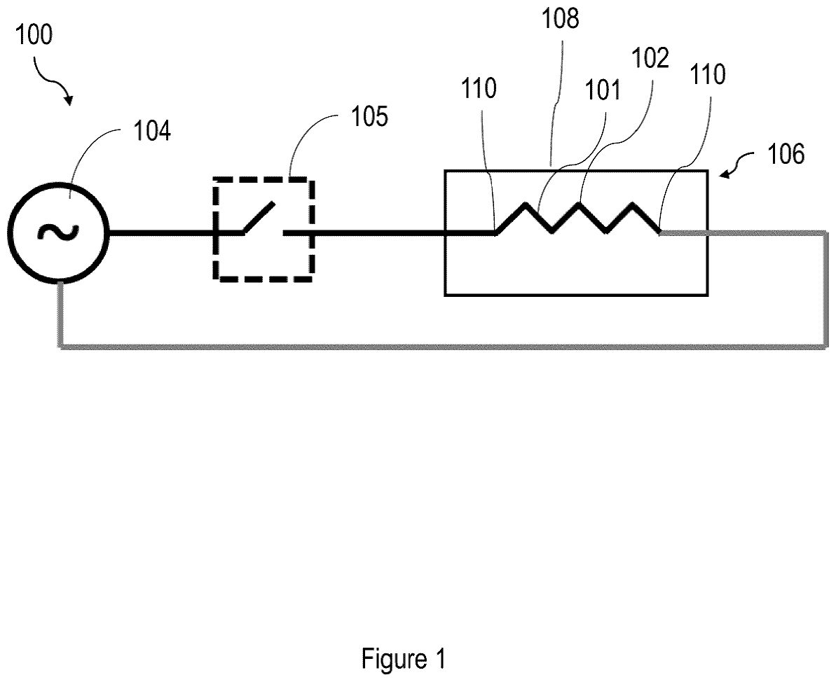

Referring now to FIG. 1 shown therein is block diagram of a system for Large Scale Joule Heat Conversion 100, according to an embodiment. The system 100 produces a resultant product from a feedstock 101. The system 100 produces graphene three to four orders of magnitude in mass higher than disclosed in previous methods that convert carbon into graphene via joule heating.

The system 100 further includes an AC power source 104. The AC power of the system may be any AC source 104 derived form an electrical grid or an industrial generator. The AC source 104 may be suitable for industrial operation. The preferred AC source 104 is rated from 100 to 1500 VAC root mean square (RMS). The preferred AC source 104 has a peak RMS current rating from 100 to 20000 Amps (A). The AC source 104 may be 60 Hertz (Hz) or 50 Hz AC source. In another configuration of the system the AC source 104 may have a signal in the range from 60 to 1000 Hz. In another configuration of the system the AC source 104 may be half rectified. In a half rectified AC source 104 only one side of the AC signal is used for joule heating of the feedstock 102. In another configuration of the system the AC source 104 may be fully rectified. The AC source 104 may be first transformed from a primary voltage to a secondary voltage. The transformation may be via transformers. The primary voltage may be 13 kVAC. The secondary voltage may be any voltage from 100 VAC to 1500 VAC. In a preferred configuration the secondary voltage may be one or more of 480 VAC and 600 VAC. The secondary voltage is used for joule heating the carbon feedstock load 102 to convert it into graphene. The secondary voltage may be a single phase or 3 phase power. The power lines of the secondary voltage may be configured to operate in Delta configuration. The power lines of the secondary voltage may be configured to operate in Wye configuration.

The system 100 further includes a controller 105. The controller 105 may be any device that can stop the flow of current such as an electrical switch. Stopping the electrical current allows the controller 105 to allow sample insertion and removal, to control the energy dose, and to provide safety interrupts. The controller 105 may be a relay that can be controlled with a logic decision. The relay mechanism 105 may be controlled via one or more of mechanical, electrical, electromechanical, electrostatic, pneumatic, or hydraulic principles.

The controller 105 may include multiple relays. The multiple relays may include one or more relay for each dose, for safety and for operation. For high current operation a controller 105 may consist of multiple relays operating in parallel. The relays operating in parallel limit the maximum current per relay and evenly distribute the high current among the multiple relays. The relay or relay assembly is suited to operate at voltages from 100 to 1500 VAC and currents from 100 to 20000 Amperes. Examples of electrical and electromechanical relays include solid state relays (SSR) and gas discharge tubes. Example of mechanical relays include contactors and mercury vapor switches. Example of high-power solid-state relays include thyristors, SCRs, triacs, and IGBTs. In some cases, at least two SCRs have to be connected in reverse parallel to accommodate the diode behavior of the SCRs and allow bidirectional current flow.

The system may include software controllers needed for successful control and meter the AC power for graphene conversion.

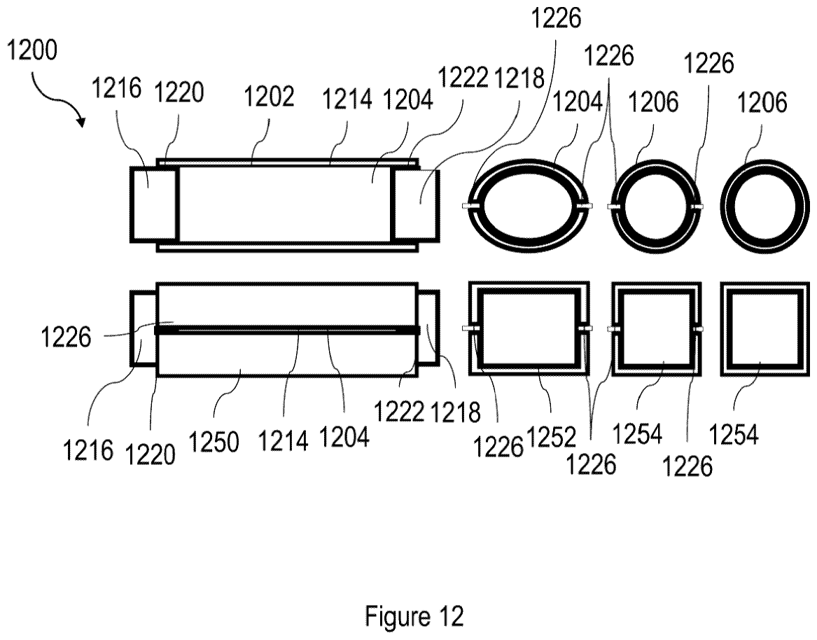

The system further includes a constraining reservoir 106. The constraining reservoir constrains the feedstock 101 during heating. The constraining reservoir may be one or more of the reservoirs 1200, 1300, 1600, 2006, 2104, 2302, 2402, 2502, 2602, and 2702 of FIGS. 12, 13, 16, 20, 21, and 23-26 respectively, further described herein below. One constraining reservoir 106 geometry may be a tube. The tube may be cylindrical or may be a hollow rectangular profile. The tube may be assembled from two half tubes (split longitudinally) or a rectangle/brick shape tube. It is desirable that the aspect ratio of length over diameter (L/D) for round tubes of the confined grain feedstock is larger than 0.1, and length over hypotenuse (L/H) for rectangular tubes also be larger than 0.1. In an embodiment the L/D or L/H ratio is between 0.1 and 50, and the preferred L/D or L/H ratio is between 2 and 6.

The constraining reservoir 106 includes a constraining structure 108. The constraining structure is configured to constrain a resistive load 102. The constraining structure 108 may also constrain the resistive load during compression. The friction of the constraining reservoir, which depends on the material and roughness of the constraining reservoir, and the pressing force onto the feedstock, determine the compressed length (L) of the feedstock inside a tube with known diameter.

Due to the high temperatures generate during the joule heating process the constraining structure 108 includes high temperature, electrically insulating materials, such as electrically insulating materials including at least one of the group comprised of: quartz, ceramic, cement, concrete, silicon carbide, magnesium-based refractories (magnesia-carbon, dead-burned magnesite —MgO, magnesite-chrome, and magnesia-alumina spinel), dolomite (dead-burned dolomite, and resin bonded dolomite), aluminum-based refractories (alumina-magnesia-graphite, fireclay refractory having hydrated aluminum silicates, high alumina refractories, and phosphate bonded high alumina). Other suitable materials include BN, Al₃N₄, Si₃N₄. Alternatively, the constraining structure 108 may be made from lower performance materials but be coated with high temperature castable materials.

The constraining reservoir 106 further includes at least two electrodes 110. The electrodes 110 transmit an electrical current through the resistive load 102 to joule heat the feedstock 101. The electrodes 110 electrically contact the resistive load 102. The contact may only be with fraction of the resistive load 102. The feedstock 101 may be compressed using one or more electrodes 110. The electrodes 110 may that fit tightly into the constraining structure 108. The electrodes 110 may block the feedstock 101 from leaving the constraining reservoir. The constraining reservoir 106 may include an electrode 110 for each side of the constraining structure 108.

The electrodes 110 may be applied on opposing ends of the constraining reservoir 106. The electrodes 110 may also be positioned at some defined angle between them as long as electrical current can be passed through the volume of the feedstock 101.

The electrodes 110 may be cylindrical graphite electrodes. Due to the high temperatures generate during the joule heating process the electrodes 110 of the constraining reservoir include high temperature, electrically conducting materials, such as graphite, brass, copper, copper wool, stainless steel, or tungsten.

The resistive load 102 draws a current from the power source 104. The current is drawn according to Ohm's law based on the voltage applied. The resistive load heats up due to the current drawn. The heating is according to Joule's law (joule heating). The heating power P is:

$${P}_{R} = I {V}_{R} = {I}^{2} R = {V}_{R}^{2} R = \frac{{V}^{2} R}{( {R}^{2} + {X}^{2} )}$$

where I (Amps) is the current thought the feedstock load, V_{R} (Volts) is the voltage between the sample, V is the applied voltage, X is the Reactance of the inductor or capacitor (if any), and R (Ohms) is the feedstock load resistance. The range of heating power is from 0.01 to 30 MW RMS power. The heating of resistive load converts the feedstock into the resultant product. The resultant product may be graphene.

The resistive load 102 includes the feedstock 101. The bulk density of the grain feedstock depends on the feedstock type and the grain size. The feedstock 101 may be a carbon source in that it is carbon based. The carbon-based feedstock 101 may be of one or more of a powder, grain, pellet, and chunk morphology. The morphology of the carbon feedstock can be one large pill constrained in a reservoir volume or multiple smaller pills constrained in a reservoir volume, wherein the flashing of a carbon-based pill is described in PCT/CA2020/051368 which is herby incorporated as reference. The morphology of the carbon feedstock can be super fine grain or powder (<10 μm), micro fine grain (10 μm to 45 μm) or powder, very fine grain (45 μm to 125 μm), fine grain (125 μm to 355 μm), coarse grain (355 μm to 1700 μm), pellets (0.5 to 3 mm), medium chunks (0.8 to 3 mm), chips (3 to 25 mm), and MetCoke breeze (3 to 15 mm). The carbon-based feedstock 101 may have a mass between 0.1 to 300 kg, a bulk resistance between 0.5 to 5000 Ohms, and grain size from 5 nm (for carbon black) to 15 mm (MetCoke breeze).

The feedstock 101 may be a carbon source in that it is carbon based. The carbon-based feedstock material 101 may include one or more of metallurgical coke, anthracite coal, green petroleum coke, calcinated petroleum coke, recycled-tire carbon black, carbon black, char, bio char, wood char, plant char, ground coffee, coffee char, polymer, plastic, plastic char, plastic ash, polypropylene, polyethylene, polyurethane, and Styrofoam. The carbon-based feedstock material may have carbon content from 10% to 99.9% on weight basis. Another source of carbon-based feedstock 101 may include residual carbon from the process of hydrocarbon decomposition for hydrogen extraction. One example of this decomposition process is the production of turquoise hydrogen from methane.

The feedstock 101 may comprise a second material. The second material may bind the feedstock material 101 from a grain or powder form into a pellet or pill form. The second material 101 may include one or more of water, ground coffee, corn starch, pine bark, polyethylene microwax, wax, chemplex 690, cellulose, naptenic oil, asphaltenes, gilsonite, water, Carboxy Methyl Cellulose (CMC), lignan, lignin, sodium lignosulfonate, calcium lignosulfonate, developmental sodium lignin, desugared calcium lignosulfonate, ammonium lignon sulfonate, calcium lignin, brewers condensed solubles, de-sugarized beet molasses. In an embodiment the percent of second binding material 102 with respect to the feedstock is between 1 to 10% on weight bases. The preferred percent of second binding material is from 1 to 5%.

The second material may improve conductivity of the feedstock material 102. The second conducting material includes at least one of calcinated petroleum coke, tire carbon black, carbon black, metallurgical coke, turbostratic graphene, and carbon nanotubes. In an example the percent of second conducting material with respect to the feedstock is between 1 to 15% on weight bases. The preferred percent of second conducting material is from 1 to 5%.

The second material may act as a filler. The filler can be used to adjust the packing density, electric conductivity, and thermal conductivity of the feedstock 101. The second sacrificial material can also be used to facilitate gas release during joule heating process. In some examples, the filler can also serve as templates to control the morphology of graphene. The filler can be any one of Fe, Cu, Al, or other transition or main group metals; TiO2, Al₂O₃, SiO2 or other oxides; NaCl, KCl, MgCl2, CaCO3, CuSO4, or other metal salts; KOH, NaOH, or other base or any combination of the above. The filler may be added to the feedstock by mixing the feedstock with dry nano or micro particles or with a liquid solution comprising the filler material. For example, dissolving FeCl2 or FeCl3 with water and then mixing with feedstock, waiting for set time, and drying the liquid phase of the solution, leaving feedstock doped with second feeder material. Other example includes adding Ni filler via NiCl2. The filler may be burned out or partially burned out or stay inert during the joule heating. The filler may be removed in situ during flash joule heating or be removed afterward using solvent, acid, or base wash.

The feedstock material 101 may comprise fillers that participate the reaction during joule heating process. After joule heating, the flashed filler can remain on graphene surface as nanoparticles, clusters, or atomically dispersed in graphene network. In some examples, the flashed filler can be embedded inside graphene. These materials can serve as catalyst for other reactions, such as Heck reaction, Fischer-Tropsch reaction, dehydrogenation, Suzuki reaction, Haber-Bosch reaction, water oxidation, hydrogen evolution reaction, oxygen reduction reaction, CO2 reduction, or other reactions. These materials can also be used as functional materials such as photovoltaic materials, magnetic materials, thermoelectric materials, and other functional materials. The filler can be Pt, Pd, Ru, Au, Ir, Rh, Co, Fe, Cu, Ni, Zn, Bi, or other transition or main group metals; Pt(acac)2, AuCl3, AgNO3 or other metal precursors, TiO2, Al₂O₃, SiO2 or other oxides or combinations of any of the above. The catalyst may be added to the feedstock by mixing the feedstock 101 with dry nano or micro particles or with a liquid solution comprising the catalyst material.

The feedstock material 101 may comprise metal-based catalysts. The catalyst will facilitate the growth of graphene or carbon nanotubes or carbon onions during the joule heating process. The catalyst can be Fe, Co, Ni, Cu, or other transition metals; iron acetate, iron chloride, iron acetylacetonate, or other metal salt; iron oxide, cobalt oxide, or other transition metal oxide, iron hydroxide, nickel hydroxide or other transition metal hydroxide, TiO2, Al2O3, SiO2 or other oxides, or any combination of the above. The filler or catalyst can be single or multi-metal components. The catalyst may be added to the feedstock by mixing the feedstock with dry nano or micro particles or with a liquid solution comprising the catalyst material.

In an embodiment the second process material is an anode material of a Li-Ion battery including one of the group comprising silicon, silicon oxide (SiOx), SiOx-based anode materials, and Si—O—C-based anode materials. The Li-Ion anode material may have a morphology that includes at least one of the group comprised of: particles, spheres, nanospheres, microspheres, rods, nanowires, and microwires. The Li-Ion anode material may be non-porous, porous, nanoporous, microporous, and having layered structures. The Li-Ion anode material may be a new material or recycled Li-Ion anode material. After joule heating, the silicon based material can be dispersed in the graphene network, it can be partially or fully coated by graphene, form clusters of silicon based material and graphene, or the silicon based material may migrate or diffuse within the layers of the graphene, or any combination thereof. In an embodiment the resulting composite of anode material and graphene improves the power density and cycle life of the silicon-based anode by preventing silicon caused degradation. The anode materials can also be other transition metal oxides, such as titanium oxide, vanadium oxide, niobium oxide, molybdenum oxide, tungsten oxide, or transition metal carbide, such as titanium carbide, vanadium carbide, niobium carbide, molybdenum carbide, tungsten carbide, or metals that alloy with Li, such as aluminum, bismuth, cadmium, magnesium, tin, antimony.

In one example of this invention the second process material is a cathode material of a Li-ion battery including the group comprising of Lithium Cobalt Oxide (LiCoO2)—LCO, Lithium Manganese Oxide (LiMn2O4)—LMO, Lithium Nickel Manganese Cobalt Oxide (LiNiMnCoO2)—NMC, Lithium Iron Phosphate (LiFePO4)—LFP, Lithium Nickel Cobalt Aluminum Oxide (LiNiCoAIO2)—NCA, and Lithium Titanate (Li2TiO3)—LTO, but not limited to the group. The Li-Ion cathode material from this invention may be a new material or recycled the Li-Ion cathode material. In one example of this invention the resulting composite of cathode material and graphene improves the power density and cycle life of the cathode.

In an embodiment the bulk density of the feedstock material 101 is between 0.1 to 1.4 g/cc with a preferred feedstock bulk density below 1 g/cc.

In an embodiment a Metallurgical Coke (MC) feedstock grain with #12-20 mesh (1.52-0.86 mm) fraction size has a bulk density of 0.64 g/cc, and in another example MC grain with #45-60 mesh (0.355-0.23 mm) fraction size has a bulk density of 0.90 g/cc, and yet in another example MC with breeze (3-15 mm) fraction size has a bulk density of 0.55 g/cc.

In a further embodiment Calcinated Petroleum Coke (CPC) feedstock grain with #12-20 mesh (1.52-0.86 mm) fraction size has a bulk density of 0.80 g/cc.

In a further embodiment recycled-tire carbon black (TCB) feedstock pellets with 1-3 mm fraction size has a bulk density of 0.52 g/cc.

In a further embodiment bio derived char (BC) feedstock with medium chunks (0.8 to 3 mm) fraction size has a bulk density of 0.21 g/cc. In a further embodiment, BC feedstock pellets with 0.5 to 3 mm fraction size has a bulk density of 0.47 g/cc.

In a further embodiment green petroleum coke (GPC) feedstock grain with #16-18 mesh (1.13 to 0.98 mm) fraction size has a bulk density of 0.7 g/cc.

In an embodiment the tube inner diameter (ID) and therefore the constraining feedstock diameter is in the range from 1.6 to 50 cm, and the constraining feedstock length is in the range from 1 to 310 cm.

In an embodiment (K2-4) the diameter of the constraining tube is 7.5 cm. 1 kg of MetCoke (MC) feedstock grain with #12-20 mesh (1.52-0.86 mm) fraction has confined grain feedstock length of 36 cm and aspect ration L/D of 4.8.

In an embodiment (K3-9) the diameter of the constraining tube is 7.5 cm. 2 kg of MetCoke (MC) feedstock grain with #12-20 mesh (1.52-0.86 mm) fraction has confined grain feedstock length of 73 cm and aspect ration L/D of 9.7.

In an embodiment (K3-16) the diameter of the constraining tube is 11.3 cm. 5 kg of MetCoke (MC) feedstock grain with #12-20 mesh (1.52-0.86 mm) fraction has confined grain feedstock length of 82 cm and aspect ration L/D of 7.3.

In an embodiment (K3-18) the diameter of the constraining tube is 11.3 cm. 7 kg of CPC grain with #10-20 mesh (1.91-0 m.86 m) fraction size has confined grain feedstock length of 72 cm and aspect ration L/D of 6.4.

In an embodiment (K3-22) the diameter of the constraining tube is 15 cm. 13 kg of CPC grain with #10-20 mesh (1.91-0 m.86 m) fraction size has confined grain feedstock length of 78 cm and aspect ration L/D of 5.2.

In an embodiment (KX-1) the diameter of the constraining tube is 40 cm. 300 kg of CPC grain with #10-20 mesh (1.91-0 m.86 m) fraction size has confined grain feedstock length of 250 cm and aspect ration L/D of 6.3.

In an embodiment (K4-2) the diameter of the constraining tube is 7.5 cm. 1 kg of recycled-tire carbon black (TCB) feedstock pellets with 1-3 mm fraction size has confined feedstock length of 46 cm and aspect ration L/D of 6.1.

In an embodiment (KX-2) the diameter of the constraining tube is 50 cm. 300 kg of recycled-tire carbon black (TCB) feedstock pellets with 1-3 mm fraction size has confined grain feedstock length of 290 cm and aspect ration L/D of 5.8.

In an embodiment (K4-10) the diameter of the constraining tube is 7.5 cm. 0.65 kg of bio derived char (BC) feedstock with medium chunks (0.8 to 3 mm) fraction size has confined grain feedstock length of 70 cm and aspect ration L/D of 9.3.

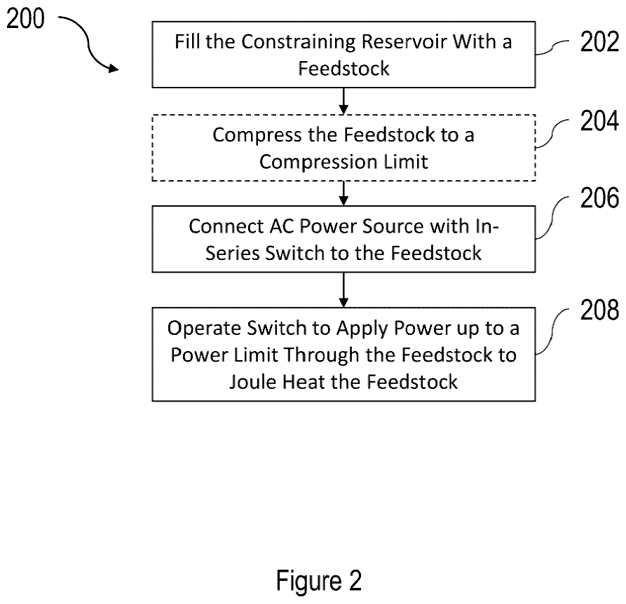

Referring now to FIG. 2 shown therein is flow diagram of a method for large scale joule heat conversion of a feedstock into a resultant product 200, according to an embodiment. The system by which the method 200 is achieved may be the system 100 of FIG. 1. The method 200 is large scale in that it produces a resultant product with a mass approximately 0.1 Kg or larger. The process of joule heating 0.1 to 300 kg feedstock is not obvious to one skilled in the art of flash joule heating masses from 1 to 10 g due to the significant increase in electrical power requirements, mechanical constraints and gas and heat dissipation requirements that change significantly with a larger feedstock mass (10 g and beyond).

At 202, feedstock material is filled and/or packed into a constraining reservoir. The constraining reservoir may be one or more of the reservoirs 1200, 1300, 1600, 2006, 2104, 2302, 2402, 2502, 2602, and 2702 of FIGS. 12, 13, 16, 20, 21, and 23-26 respectively, further described herein below. The feedstock material may be the feedstock 102 of FIG. 1. In an embodiment, the feedstock has a mass between 0.1 and 300 kg.

At 204, the grain feedstock may be compressed. The compression continues until the resistance of the feedstock grain is between 0.5 and 5000 Ohms of bulk resistance. The compression force is kept in place during joule heating. In some examples the compression force on the feedstock may be present during the filling and packing of the feedstock into the reservoir or only in the beginning time segment of the joule heating process. The compression may be omitted if the feedstock grains or pellets are filled in or leveled evenly within the space within the reservoir and between the electrodes.

Higher bulk resistances (>5000 Ohms) are suitable for the joule heating process but require higher voltages and longer process times. Lower bulk resistances (<0.5 Ohms) Lower bulk resistances (<0.5 Ohms) are also suitable for the joule heating process but require higher currents to achieve joule heating. The resistance of the compressed grain feedstock depends on the feedstock material (chemical composition, and non-carbon molecules such as oxygen, nitrogen and sulfur levels), the feedstock hydrocarbon content, the feedstock material ash content, the feedstock material volatile organic compounds (VOCs), the feedstock moisture content, the feedstock grain size, the cross-section area of the constrained feedstock, the length of the constrained feedstock, the friction of the constraining reservoir walls, and the force compressing the grain.

The feedstock grain resistance normalized with respect to the geometry can be expressed in units of resistivity (Ohms*cm). The resistivity of the feedstock grain ranges from 0.3 to 700 Ohms*cm. The preferred feedstock resistivity for feedstock with high bulk density (0.5 to 1 g/cc) is in the ranges from 0.3 to 5 Ohms*cm, the resistivity for feedstock with medium bulk density (0.3 to 0.7 g/cc) is in the ranges from 20 to 100 Ohms*cm, and the resistivity for feedstock with low bulk density (<0.5 g/cc) is in the ranges from 100 to 700 Ohms*cm. Higher resistivities (>700 Ohms*cm) are suitable for the joule heating process but require higher voltages and longer process times. Lower bulk resistivities (<0.3 Ohms*cm) are also suitable for the joule heating process but require higher currents to achieve joule heating.

The feedstock may be compressed in a longitudinal direction of the constraining reservoir. This compression may be between two opposing electrodes, along the direction of the applied electrical power through the electrodes. The electrodes may be used to apply the compression force to compress the feedstock.

The feedstock may be compressed along a direction perpendicular to a line between two opposing electrodes. In this embodiment the compression is perpendicular to the direction of the applied electrical power.

The electrodes are in electrical contact with the feedstock. The electrodes function as conduits for applying electrical power to the feedstock needed to achieve joule flash heating process that converts carbon-based feedstock into graphene.

At least one side of the reservoir must be moved with respect to an opposing side. However, the remaining sides may remain static. In an embodiment the compression force is between 10 to 500 kg, and face pressure from 20 to 1200 kPa to achieve a feedstock resistivity from 0.3 to 700 Ohms*cm.

In an embodiment (K2-4) 1 kg of MetCoke (MC) feedstock grain was compressed to length of 36 cm with force of 94 kg to obtain feedstock grain resistance of 0.6 Ohms (resistivity of 0.73 Ohms*cm).

In an embodiment (K3-18) 7 kg of calcinated pet coke (CPC) feedstock grain was compressed to length of 72 cm with force of 76 kg to obtain feedstock grain resistance of 0.5 Ohms (resistivity of 0.66 Ohms*cm).

In an embodiment (K4-2) 1 kg of recycled-tire carbon black (TCB) feedstock pellets were compressed to length of 46 cm with force of 140 kg to obtain feedstock grain resistance of 44 Ohms (resistivity of 43 Ohms*cm).

In an embodiment (K4-10) 0.65 kg of bio derived char (BC) feedstock chunks were compressed to length of 70 cm with force of 184 kg to obtain feedstock grain resistance of 372 Ohms (resistivity of 235 Ohms*cm).

At 206, a power source output is connected with the feedstock inside a constraining reservoir volume (the load). The power source may be the power source 104 of FIG. 1. The load may be resistive load 106 of FIG. 1. The connection may be in series. The feedstock is electrically conductive. The feedstock may also be carbon-based. In an embodiment, the feedstock is compressed, and the compression force may be left to act on the feedstock while the power source is connected. The relay switch is in series with the load. The switch may be the switch 108 of FIG. 1.

At 208, a power is applied to the feedstock by operating the relay switch. As the power is applied the compression force of 206 may still be in place. In applying the power to the feedstock, the resistive load draws a current. The current is drawn according to Ohm's law based on the voltage applied. The resistive load heats up due to the current drawn. The heating is according to Joule's law (joule heating). The heating power P is:

$${P}_{R} = I {V}_{R} = {I}^{2} R = {V}_{R}^{2} R = \frac{{V}^{2} R}{( {R}^{2} + {X}^{2} )}$$

where I (Amps) is the current thought the feedstock load, V_{R} (Volts) is the voltage between the sample, V is the applied voltage, X is the Reactance of the inductor or capacitor (if any), and R (Ohms) is the feedstock load resistance. The range of heating power is from 0.01 to 30 MW RMS power. In an embodiment, the power source is configured to have peak RMS current limit of 100 to 20000 A and voltage from 100 to 1500 VAC RMS. The heating of resistive load converts the feedstock into the resultant product. In an embodiment, the harder morphology Coke feedstock materials require peak power of 0.1 to 5 MW/kg to convert the carbon feedstock into graphene, and in another example the softer morphology carbon black and char feedstock materials require peak power of 0.05 to 1 MW/kg to convert the carbon feedstock into graphene.

In embodiments including multiple resistive loads and corresponding switches, the system may be configured to operate consecutively, one at a time, by coordinating the operation of the switches and only allowing one phase of the power to be engaged at any time (process one feedstock load at time). There may be a short delay between switching the phases due to switch control electronics reasons. In one configuration of this consecutive operation the phase switching is continuous without significant pause, wherein after the last of the phases is turned off the first of the phases first phase is turned on again. In this embodiment, the converted feedstock loads in the joule heating systems are exchanged with unconverted feedstock loads before the next joule heating process is engaged. In another configuration of this consecutive operation example, there is an intentional pause after each phase switch cycle. This pause allows time for the feedstock load samples to cool and/or be exchanged.

In another embodiment, the joule heating systems (one pre phase) are configured to operate concurrently. The operation is accomplished by coordinating the operation of the switches and allowing all phases of the power to be engaged at the same time (process all 3 feedstock loads at the same time). Since each of the phases is 120 degrees offset from the previous phase, the power load on each phase is mainly balanced.

For a conversion of a carbon-based feedstock-to-graphene the feedstock has to be rapidly heated to a temperature in the range from 1800° C. to 3000° C. and have a dose of deposited energy E (Joules) in the range from 3 to 20 MJ/kg. Some feedstocks, like carbon blacks, may require energy deposition in the range from 8 to 40 MJ/kg. Part of the energy is consumed to heat a mass of feedstock from room temperature to the process temperature, and part of the energy is the conversion energy from carbon to graphene as described in Nature. The conversion energy depends on the material of the feedstock. Heat losses come from radiation losses, conduction losses, water moisture evaporation heat, and unwanted residual material sublimation heat. In an embodiment the joule heating process time may be from 1 sec to 20 min. In a further embodiment the joule heating process time may be from 30 sec to 5 min.

In general, grained feedstock material under some amount of compression that is keeping the grains in contact to each other (not free running) will have a compound bulk resistance made from the sum of resistances of each grain and the contact resistance between the grains. Under the joule heating process, the bulk feedstock resistance will change in a non-linear manner as the grains heat up and changes thermal conductivity, the free water in the feedstock evaporates, some of the hydrocarbons burn off at different temperatures, some of the non-carbon materials sublimate at different temperatures, and the carbon undergoes conversion from carbon to graphene. The non-linear behavior of the feedstock bulk resistance will result in non-linear current flow and resulting in non-linear heat and power deposition. In general, the feedstock bulk resistance drops as the feedstock heats up but not always. In some cases, the bulk resistance may increase again after reaching a minimum value. Since energy is an integral of the power over time, the energy deposited to the feedstock will also deposit in a non-linear manner.

In one configuration the joule heating process is repeated at rates from 15 sec to 10 min. The repeated joule heating process can be from a single phase, from three phases (consecutively or concurrently), it can be from a Wye transformer configuration or from Delta transformer configuration, it can be repeated with minimal pause between processes, or it can be repeated with intentional pause between processes, it can be done with a single joule heating system, three joule heating systems, and multiple joule heating systems. For a typical 8 hour (480 min) manufacturing shift and depending on the heating process is repeated at rates the grid power will be utilized from 50 to 2000 times per shift wherein each joule heating process requires 0.01 to 30 MW RMS power and peak RMS current loads of 100 to 20000 A. The heavy-duty power cycle may therefore impact the balance and stability of the grid power.

In an embodiment the joule heating process is terminated using cumulative energy deposited to the feedstock. In a further embodiment the joule heating process is terminated using time of running current to the feedstock. In a further embodiment the joule heating process is terminated using maximum power applied to the feedstock. In a further embodiment the joule heating process is terminated using feedstock resistance measurements. In a further embodiment the joule heating process is terminated using the temperature (one spot, multiple spots, profile) of the feedstock.

In one configuration the joule heating process is terminated for safety reasons using measurements that include at least one of the group comprised of (but not limited to): max pressure in the constraining reservoir, max force to the constraining reservoir, low feedstock resistance condition, max feedstock temperature, max current or power to the feedstock, max I²*t (Amp²*time) of the electrical circuit, max electrical wire or conduit temperature, and max relay temperature. The safety interrupts may be maximum or minimum measurement or some computed trend. The process termination and safety interrupt measurements may be collected using electronic circuits, pyrometer measurements, thermocouple or thermistor measurements, thermal cameras, video feedback, force sensor, and pressure sensor. In one configuration the joule heating process is controlled using the process termination and safety interrupts measurements in conjunction with a control logic.

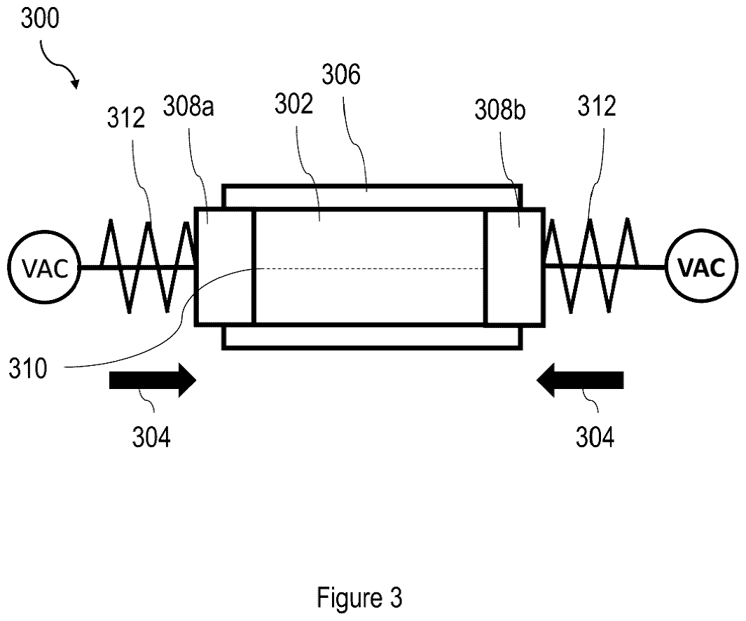

Referring now to FIG. 3 shown therein is a block diagram of a system 300 for longitudinal compression of feedstock for large scale joule heating, according to an embodiment. The system 300 may be the system 100 of FIG. 1. The feedstock 302 is be compressed in a longitudinal direction 304 of the constraining reservoir 306. This compression is between two opposing electrodes 308a and 308b, along the direction of the applied electrical power through the electrodes 308. The electrodes 308a and 308b may be used to apply the compression force to compress the feedstock 302.

The compression system further includes at least one spring 312. The spring 312 pushes an electrode 308a or 308b with respect to some fixed point until the desired process bulk feedstock resistance or process feedstock resistivity is achieved. In another example the springs 312 can be replaced with pneumatic pistons (not shown) that act in place of the springs. The electrodes 308 in this configuration move along the confines of the reservoir 306. The movement accounts for changes on the feedstock 302 volume as it expands or contracts under the influence of the high temperature of the process. The electrodes 308 also function as conduits for applying electrical power to the feedstock 302. The application of electrical power is needed to achieve joule heating process that converts carbon-based feedstock into graphene.

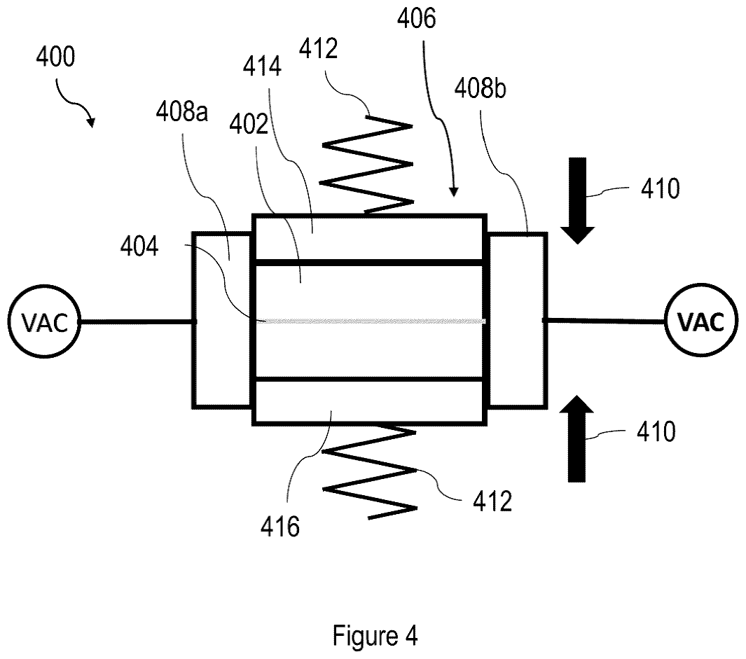

Referring now to FIG. 4 shown therein is a block diagram of a system 400 for perpendicular compression of feedstock for large scale joule heating, according to an embodiment. The system 400 may be the system 100 of FIG. 1. The feedstock 402 is compressed along a direction perpendicular to a line 404 between two opposing electrodes 408a and 408b. In this embodiment the compression 410 is perpendicular to the direction of the applied electrical power 408.

The compression system further includes at least one spring 412. The spring 412 pushes a first reservoir side 414 towards a second reservoir side 416 until the desired process bulk feedstock resistance or process feedstock resistivity is achieved. The first reservoir side 414 and second reservoir side 416 are opposing sides. In another example the springs 412 can be replaced with pneumatic pistons (not shown) that act in place of the springs. The reservoir sides 414 and 416 move along the confines of the reservoir 406. The movement accounts for changes on the feedstock 402 volume as it expands or contracts under the influence of the high temperature of the process. The electrodes 408 also function as conduits for applying electrical power to the feedstock 402. The application of electrical power is needed to achieve joule heating process that converts carbon-based feedstock into graphene. In an embodiment the compression force is between 10 to 500 kg, and face pressure from 20 to 1200 kPa to achieve a feedstock resistivity from 0.3 to 700 Ohms*cm.

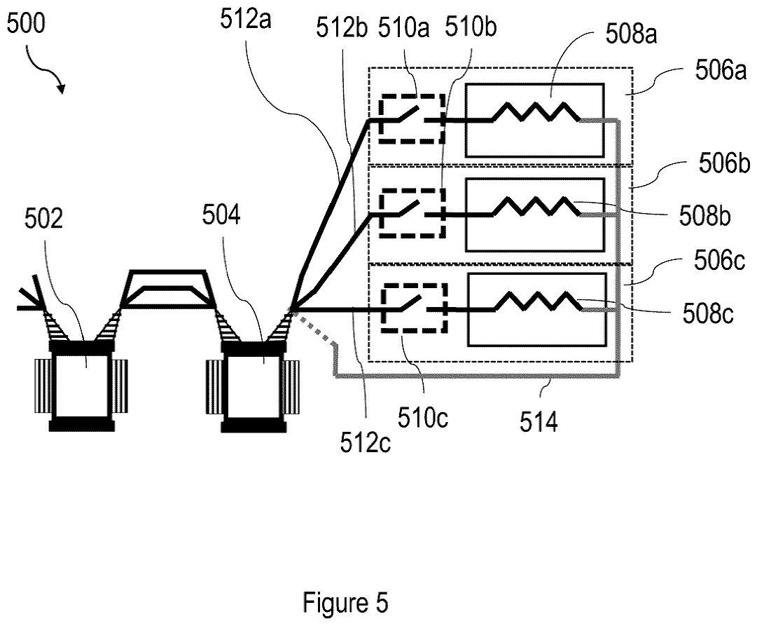

Referring now to FIG. 5, shown therein is a block diagram of a system 500 for large scale joule heating with a 3-phase wye grid power electrical configuration. The system 500 may be the system 100 of FIG. 1, according to an embodiment. The process power of the system 500 is received from an AC grid. It will be appreciated in the art of power transmission that the grid power is from a power generating plant. It will be further appreciated that the power from the generating plant is transmitted to a substation transformer 502. The substation transformer 502 transforms the power from a primary voltage to a secondary voltage. The primary and secondary voltages may be based on geographical location of the power transmission. In an embodiment the primary voltage is 138 kV, and the secondary voltage is 13.8 kV.

The system 500 further includes a factory transformer 504. The factory transformer 504 is electrically connected to the substation transformer 502. The factory transformer 504 receives the power from the from the substation transformer 502. The factory transformer 504 transforms the voltage of the power to a voltage of 100 to 1500 VAC RMS from line-to-neutral.

The system further includes a first second and third joule heating system (506a, 506b, 506c) each for joule heating a resistive load 508. Each joule heating system includes a resistive load (508a, 508b, and 508c), a switch (510a, 510b, and 510c), and a powerline (512a, 512b, and 512c) for electrically connecting a first end of the resistive load to the power supply. The wire outputs may further include a neutral wire 514. The neutral wire electrically connects a second end of the resistive load 508 to the power supply. The powerlines are configured in a wye configuration.

The voltage provided by the powerlines each include 3 phases. Each phase is paired with a joule heating system. In an embodiment, each joule heating system 506 is configured to operate consecutively, one at a time, by coordinating the operation of each switch 510 such that only one phase of the power is engaged at any time (process one feedstock load at time). There may be a short delay between switching the phases due to switch control electronics reasons. The switching may also be continuous such that the first phase is turned on after the first phase is turned off. The converted feedstock loads 508 of the joule heating systems may be exchanged with unconverted feedstock loads 508 before the next joule heating process is engaged. There may be an intentional pause after each 3-phase switch cycle to allow for the feedstock load samples 508 to be cooled and/or exchanged. Alternatively, the pause may be predominately zero, requiring rapid the max exchange time may be the time to process the resistive loads 508 other than the resistive load 508 being exchanged.

In another example, the joule heating systems 506 (one pre phase) are configured to operate concurrently. The joule heating is coordinated by coordinating the operation of the switches 510 and allowing all 3 phases of the power to be engaged at the same time (process all 3 feedstock loads 508 at the same time). Since each of the 3 phases is 120 degrees offset from the previous phase, the power load on each phase is mainly balanced.

In one configuration the factory transformer 504 is rated at 5 million volt amps (MVA) and is preferred to process feedstock masses from 1 to 10 kg, and in another the transformer is rated at 10 MVA and is preferred to process feedstock masses from 10 to 100 kg, and yet in another the transformer is rated at 30 MVA and is preferred to process feedstock masses from 60 to 300 kg.

In one configuration the joule heating process is repeated at rates from 15 sec to 10 min. The repeated joule heating process can be from a single phase, from three phases (consecutively or concurrently), it can be from a Wye transformer configuration or from Delta transformer configuration, it can be repeated with minimal pause between processes, or it can be repeated with intentional pause between processes, it can be done with a single joule heating system, three joule heating systems, and multiple joule heating systems. For a typical 8 hour (480 min) manufacturing shift and depending on the heating process is repeated at rates the grid power will be utilized from 50 to 2000 times per shift wherein each joule heating process requires 0.01 to 30 MW RMS power and peak RMS current loads of 100 to 20000 A. The heavy-duty power cycle may therefore impact the balance and stability of the grid power.

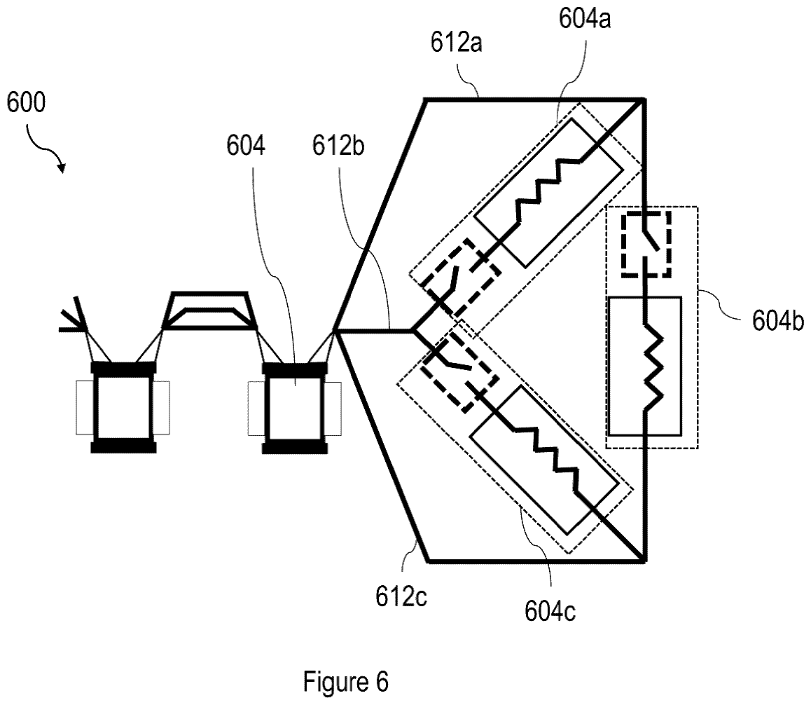

Referring now to FIG. 6, shown therein is shown therein is a block diagram of a system 600 for large scale joule heating with a 3-phase delta grid power electrical configuration. The system 600, may be the system 100 of FIG. 1. The system 600 acts similarly to the system 500 of FIG. 5. However, in the delta configuration of FIG. 6, each power line 612a, 612b, 612c electronically connects the factory transformer 604 to two joule heating systems (606a, 606b), (606a, 606c), and (606b, 606c) respectively.

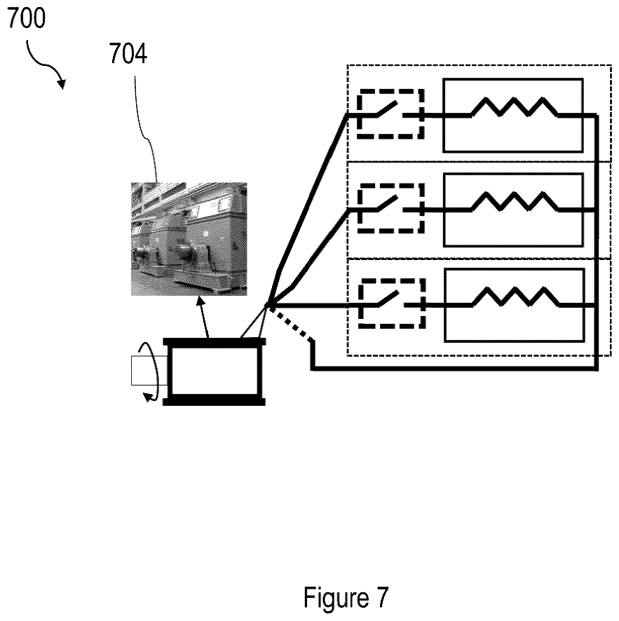

Referring now to FIG. 7, shown therein is a block diagram of a system 700 for the Large Scale Joule Heating with a Direct Power Plant Connection, in accordance with an embodiment. The system 700, may be the system 100 of FIG. 1. The system 600 is similar to the systems 500 or 600 except that process power is independent from the grid power. The system 700 includes an industrial generator 702. The industrial generator 702 supplies the process power of the system 700. Advantages of using grid independent power supply include independence from AC power grid instabilities and the elimination of the variable AC power cost that may be dependent on the peak load power. The industrial power generator 702 may be natural gas or diesel powered. In one configuration the power generator is rated from 0.1 to 5 MVA, in another configuration it is rated from 5 to 10 MVA, and yet in another configuration it is rated from 10 to 30 MVA.

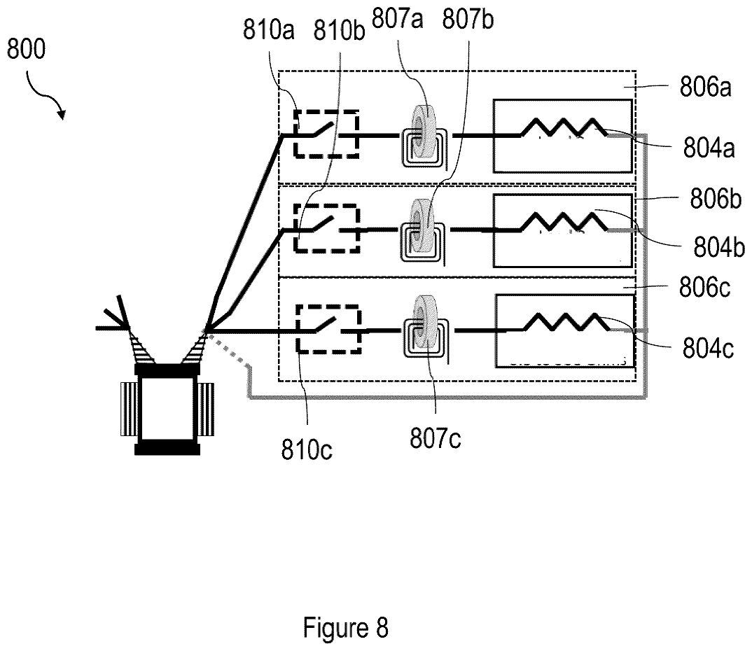

Referring now to FIG. 8 shown therein is a block diagram of a system 800 for large scale joule heating with a 3-phase wye grid power electrical configuration and reactive components. The system 800 may be the system 100 of FIG. 1. The system 800 is similar to the system 500 of FIG. 5. Each joule heating system 806a, 806b, 806c of the system 800 further includes a reactive component 807a, 807b, and 807c respectively. The reactive component may limit current spikes of the joule heating system.

When the carbon feedstock load 804 is joule heated the feedstock changes its resistive properties and becomes a non-linear resistor. In addition, as the feedstock 804 changes its properties and its density changes, the applied compression force further changes the feedstock 804 resistance. As a result, the current running through the feedstock 804 at constant power supply voltage also becomes non-linear and may spike beyond the power supply ratings. The current spikes can create thermal hot spots in the feedstock 804 that will result in a non-uniform feedstock-to-graphene process. Therefore, it is desirable to limit the current spike of the joule heating system.

In one configuration a reactive component 807 is inserted in series with the predominately resistive feedstock load 804. The reactive component 807 is preferably positioned after the relay switch 810 and before the resistive feedstock load 804. In this position, the reactive component 807 acts as current limiting element in the joule heating AC circuit. In another configuration the reactive component 807 can be inserted in other places in the electrical loop where it can operate as current limiting element.

In an electrical circuit, reactance forms the imaginary part of the complex impedance whereas resistance forms the real part. Reactance can be inductive or capacitive. The inductive reactance X_{L}=2πfL, where f is the AC frequency, 50 or 60 Hz, and L is the inductance in Henries. The capacitive reactance

$${X}_{C} = \frac{I}{2 π f C} ,$$

where f is the AC frequency, 50 or 60 Hz, and C is the capacitance in Farads. A reactive element is added to the circuit to add impedance (limit current) and add phase offset (limit power). By limiting the peak current in the AC circuit during the joule heating of the feedstock 804 excess joule heating is limited and more uniform carbon to graphene conversion is achieved.

In one configuration the joule heating system the reactive component 807 is an inductor. In an embodiment, a joule heating system has process RMS open loop voltage of 600 VAC and the peak RMS current limit is set to 10 kA. The current limiting reactance X needs to be X=600V/10000 A=0.06 Ohms. For an inductive reactance that would require an inductor L of X/(2πf)=0.06/2π60=0.2 mH. For a capacitive reactance that would require a capacitor C of 1/(2πf X)=1/2π60 0.06=44 mF. Under load, the 600 V will be reduced by the current through the load and as the current through the load reached 10 kA the voltage across the load approaches zero, thus limiting the max current through the load. If for example the current across the circuit is 10 kA, the voltage across the feedstock will be zero as all of it will appear across the reactor. If the current across the circuit is 5 kA, the voltage across the feedstock will be 300 V (half of the source voltage). If the current across the circuit is 1 kA, the voltage across the feedstock will be 540 V.

For electrical circuits that include reactive current limiting elements (capacitors and inductors) the heating power to the feedstock is the true power of the system where the True Power=Apparent Power−Reactive Power. The apparent power is the complex power that is the product of the RMS voltage and the RMS current. The reactive power losses are due to the reactive element that shifts the voltage and current relative to each other. The reactive power does not do any work, while active power does.

In one configuration of the joule heating system, the power of the joule heating process is controlled actively using a DC Converter Drive or Variable Frequency Drive (VFD). The converter has the capability to regulate the applied (output) power through a current setpoint or function. The converter maintains a constant current by varying the output voltage applied to the load to achieve the desired output power; in an alternate configuration, the system can operate on a voltage setpoint or function and vary the corresponding output current to achieve the desired output power. The control function used to regulate the constrained output parameter can be configured as a constant value, stairstep function, ramp, or any arbitrary waveform that allows a precise power profile to be applied to the feedstock.

In one example, the power supply of the flash joule heating is comprised of a twelve-pulse thyristor bridge-based DC Converter drive, which is fed from an upstream three-winding drive isolation transformer. The power supply unit utilizes the drive's armature output to provide an adjustable, controllable, direct current (DC) output at a regulated voltage to the joule heating system electrodes. In order to permit full current operation at a variety of output voltages, the converter must adjust the firing angle at which the thyristors are controlled. While the converter itself relies on input reactive power for adjustable operation, the output power factor remains a function of the load impedance as established by the material being processed. As the material physical properties change during joule heating, the load impedance reduces and the converter adjusts voltage around the current setpoint (in the case of current control) accordingly, as the load impedance approaches zero (i.e. short circuit) the system reduces output power.

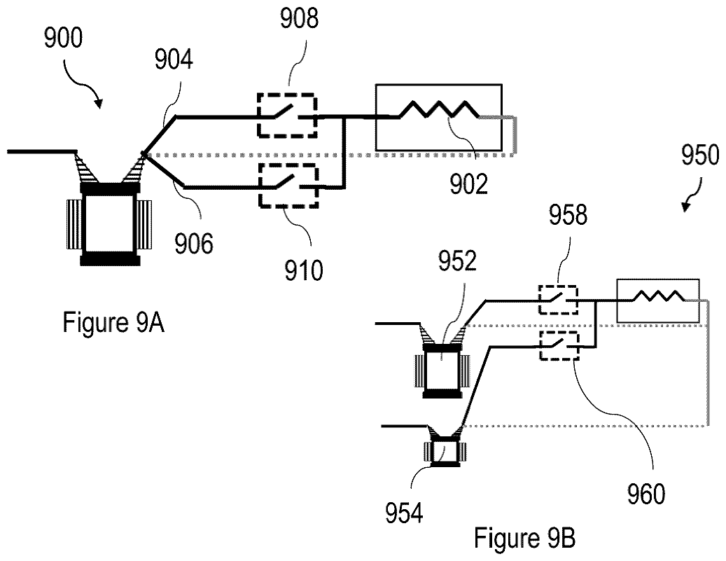

Referring now to FIG. 9A, shown therein is a block diagram of a Joule Heating System 900 with at Least 2 Voltages. The system 900 may be the system 100 of FIG. 1, according to an embodiment. The system 900 includes two voltages. The two voltages enable the system to have at least two joule heating phases. Having two heating phases is beneficial particularly when the feedstock 902 is a high-resistance material having high resistance/resistivity (>10 Ohms or >20 Ohms*cm). It will be appreciated that it is not necessary for the feedstock 902 to have a high resistance in a two voltage system 900.

The two phases are a low-power feedstock heating 904 and high-power feedstock heating 906. The low-power joule heating 904 may also be referred as preheating 904. The low-power joule 904 heating is mainly due to the high resistance/low current condition of the sample 902 and the high-power joule heating is mainly due to the low resistance/high current condition of the sample 902. The energy deposition during the low-power joule heating phase 904 goes towards heating the feedstock, evaporating free water, burning off hydrocarbons, and sublimating some non-carbon materials. In an embodiment the low-power joule heating phase 904 time is from 1 sec to 30 min, and in another example the low-power joule heating phase 904 time is from 30 sec to 5 min.

In one embodiment of the process the preheating step 904 may be done in a separate batch or separate reservoir as to optimize production of graphene based on size of the batch and the process time. For example, a preheating batch may be from 5 to 300 kg and take from 10 min to 30 min, wherein a high-power joule heating process may have a batch from 5 to 10 kg and take 1 to 5 min. In addition, the process reservoir for the preheating process 904 may be constructed form lower temperature materials than the reservoir used for high power joule heating process 906. In one example the preheating reservoir can be constructed using Portland cement based concrete, SiC or refractory cement based materials.

The energy deposition during the high-power joule heating phase 906 goes towards heating the feedstock 902, sublimating non-carbon materials, and converting carbon to graphene. In an embodiment the high-power joule heating 906 profile time is from 1 sec to 5 min, and in another example the high-powerjoule heating 906 profile time is from 30 sec to 2 min.

In one configuration the power supply operates with a single voltage output during the low-power and high-power joule heating phases as the feedstock 902 resistance drops during the joule heating process. In another configuration the power supply can operate using at least 2 voltage outputs, high and low voltage. The high voltage is applied during the low-power phase 904 of the heating and the low voltage is applied during the high-power phase 906 of the heating. The high voltage is applied with a high voltage switch 908. The low voltage is applied with a low voltage switch 910.

It is preferred that the max time lag when switching between 2 voltages be less than 10 AC cycles (163 ms at 60 Hz operation). At higher voltages the low-power phase 904 of the joule heating process will last shorter, adding to the production throughput. In an embodiment the high voltage is 600 V and the low voltage is 300 V. The 2-voltage configuration can be implemented to a single phase or 3-phase operation of the joule heating system.

Referring now to FIG. 9A, shown therein is a block diagram of a Joule heating system 950 with at least 2 voltages and low and high power transformers. The system 950 may be the system 100 of FIG. 1, according to an embodiment. The system 950 includes two voltages. The two voltages enable the system to have at least two joule heating phases. The system 950 operates similarly to the system 900. The system 950 includes a first transformer 952. The first transformer 952 is a high-power transformer. The first transformer is electrically connected to the low voltage switch 958. Once the feedstock resistance drops and the process enters the high-power feedstock heating process the main joule heating transformer 952 that operates at low voltages, from 300 V to 600 V, and high currents, from 1 to 20 kA, is engaged for short heating period to complete the carbon-to-graphene conversion. The shorter joule heating process cycle time enables high manufacturing rates.

The system 950 further includes a second transformer 954. The second transformer 954 is a preheating transformer. The second transformer 954 is electrically connected to the high voltage switch 960. The preheating transformer 954 may be one with high voltage rating and low current ratings that can so as to preheat the sample fast. For example, if the feedstock is heated in 15 min at 300 V then it will be heated in 2.5 min at 1800 V with the same energy dose (joules) at much lower currents (determined by the feedstock resistance).

Utilizing two transformers is beneficial as it addresses the following problem. A power supply for the process may be from a high-power transformer, 1 to 5 MVA or 1 to 20 MVA. If only one transformer is used it may be used for long times (3 to 15 min) to preheat the sample at low currents of <1000 A (determined mainly by the feedstock resistance) until the feedstock resistance drops and the process enters the high-power feedstock heating process which may last only 1 to 3 minutes and the currents running through the feedstock are high, from 1000 to 20000 A. The high-power transformer is not being utilized well for a manufacturing process.

Raman Measurements: In an embodiment the deposited energy may be used to control the quality and structure of the graphene. For example, for MC and CPC feedstocks by controlling the energy dose from 3 to 8 MJ/kg one can make controlled varying quality of graphene where the trade of is the graphene crystallinity vs graphene defect level as needed for a particular application. One figure of merit for measuring the quality and structure of the graphene is by analyzing the Raman spectra profiles of the graphene. Typical figure of merit for the graphene fabricated using this disclosure are in the range from 0.25 to 1 for 2D/G Raman measurement peaks, where in 2D/G ratio indicates high crystallinity graphene with few graphene layers. In some cases, high crystalline graphene may be helpful for strength of the graphene aided composites. A 2D peak fit with a single Lorentzian peak is an indicator of the formation of either single layer graphene or turbostratic graphene. The typical quality number for the graphene fabricated using the teachings are in the range from 0.2 to 1 for D/G Raman measurement peaks, where in D/G ratio indicates the defects in the graphene structure. In some cases, defects in the graphene structure may be helpful for dispersion of the graphene in liquids.

In an embodiment low dose (3 MJ/kg) of deposited energy may be used to make turbostratic graphene with high D/G and low 2D/G Raman measurement peaks. In an embodiment high dose (8 MJ/kg) of deposited energy may be used to make turbostratic graphene with high 2D/G and low D/G Raman measurement peaks. In an embodiment medium dose (5 MJ/kg) of deposited energy may be used to make turbostratic graphene with similar D/G and 2D/G Raman measurement peaks.

Another figure of merit for measuring the quality of the graphene is by analyzing the Thermo-Gravimetric-Analysis (TGA) profiles of the graphene. The peak temperature CT (° C.) of the TGA profile and the temperature spread dT (° C.) are indication of the crystallinity of the graphene, its lateral size, and the number of layers, and wherein a single peak indicates single graphene species.

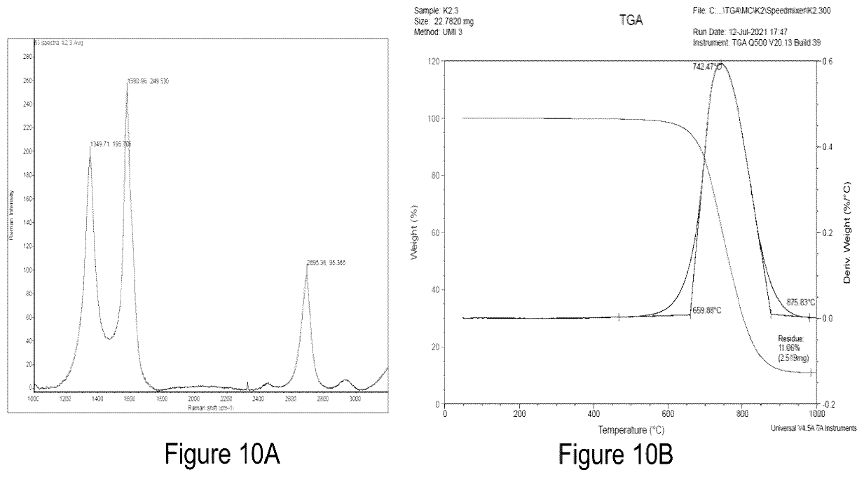

Referring now to FIGS. 10A and 10B shown therein are graphs of a Raman Signature of TG from Example 1, and a TGA Profile of TG from Example 1. In an embodiment (K2-3) a concrete tube with inner diameter of 7.5 cm was filled with 1 kg of MetCoke (MC) feedstock. After compression the feedstock resistivity was 1.1 Ohms*cm. 480 VAC was applied for 3.2 sec to deposit 3 MJ/kg of energy (low dose). The peak current was 5.1 kA, and the peak power was 3.3 MW. The resulting turbostratic graphene had Raman 2D/G ratios of 0.38 and 2D/G ratio of 0.78, as shown in FIG. 10A, indicating high quality graphene. The resulting turbostratic graphene had TGA profile with CT of 742° C., dT of 192° C., and ash content of 11%, as shown in FIG. 10B, indicating high quality graphene.

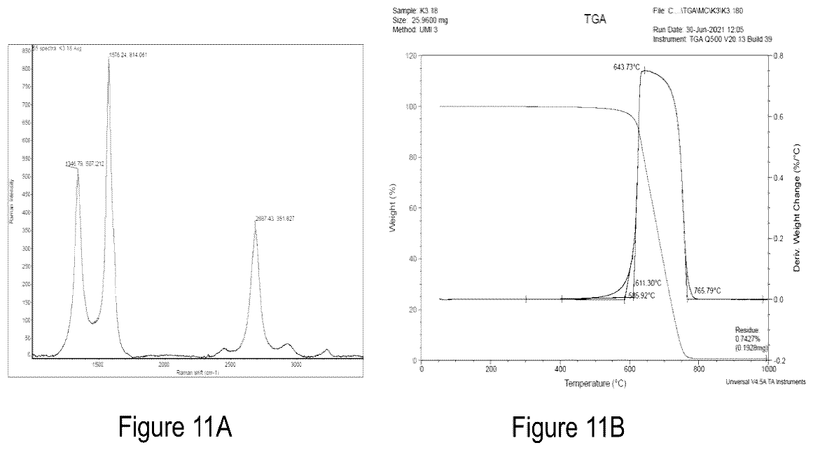

Referring now to FIGS. 11A and 11B are graphs of a raman signature of TG from Example 2, and a TGA profile of TG from example 2. In an embodiment (K3-18) a quartz tube with inner diameter of 11.3 cm was filled with 7 kg of Calcinated Pet Coke (CPC) feedstock. After compression the feedstock resistivity was 0.3 Ohms*cm. 600 VAC was applied for 73 sec to deposit 3.8 MJ/kg of energy (low dose). The peak current was 3.2 kA and the peak power was 1.9 MW. The resulting turbostratic graphene had Raman 2D/G ratios of 0.43 and 2D/G ratio of 0.70, as shown in FIG. 11A, indicating high quality graphene. The resulting turbostratic graphene had TGA profile with CT of 643° C., dT of 133° C., and ash content of 0.7%, as shown in FIG. 11B, indicating high quality graphene.

Referring now to FIG. 12 shown therein is a side view, and various cross sectional views of a constraining reservoir 1200, according to various embodiments. The constraining reservoir 1200 may be the constraining reservoir 106 of FIG. 1.

The constraining reservoir 1200 may be configured as a round tube constraining reservoir 1202. The round tube 1202 may have an elliptical cross section 1204. The round tube 1202 may further have a circular cross section 1206.

The constraining reservoir 1200 reservoir may also be configured as a rectangular tube constraining reservoir 1250. The rectangular tube 1250 may have a rectangle cross section 1252. The rectangular tube 1250 may further have a square cross section 1254.

The constraining reservoir 1200 includes an internal cavity 1214 the internal cavity 1214 is filled with the feedstock 1204. The internal cavity may be filled through openings at a first end 1220 and a second end 1222 of the constraining reservoir 1200.

The constraining reservoir 1200 further includes a first electrode 1216 and a second electrode 1218. The electrodes 1216 and 1218 are positioned at a first end 1220 and a second end 1222 of the constraining reservoir 1200. The first end 1220 and the second end 1222 are opposing along a longitudinal axis of the constraining reservoir 1200. The electrodes 1216 and 1218 may plug the openings at the first end 1220 and second end 1222 of the constraining reservoir 1200, respectively. Plugging the openings may further constrain the feedstock 1204. The electrodes move along the confines of the constraining reservoir 1200 to account for changes in the feedstock 1204 volume. The feedstock 1200 expands or contracts under the influence of the high temperature of the method 200 of FIG. 2. The shape of the electrodes 1216 and 1218 match the cross-section of the constraining reservoir 1200

The constraining reservoir 1200 is configured to allow gasses released during the feedstock 1204 conversion. Under joule heating process, the feedstock is rapidly heated to a temperature in the range from 1800° C. to 3000° C., over periods of seconds to minutes and the feedstock grain undergoes changes such as thermal expansion of the feedstock, evaporation of free water in the feedstock, hydrocarbons burn off, non-carbon materials sublimation, and carbon to graphene conversion. These changes may result in generation of process gas that may have high pressures, from 10 to 300 Psi, that if not controlled may cause damage to the containing reservoir or loss of the feedstock grain as it is pushed out by the high pressure. Therefore, the containing reservoir needs to have the means to reduce the effects of the high-pressure process gas.

The gasses may escape through gaps between the confines of the constraining reservoir 1200 and the electrodes 1216 and 1218. The constraining reservoir 1200 may further include a longitudinal split 1226. The longitudinal split 1226 splits the constraining reservoir into at least two segments. The longitudinal split 1226 runs along the length of the constraining reservoir 1200 and the feedstock 1204. The longitudinally split 1226 is a gap that allows gas to escape. As the gap runs along the length of the feedstock 1204, the gap allows the gas generated anywhere in the feedstock 1204 to travel the shortest possible distance (radius of the tube) to exit the constraining reservoir 1200.

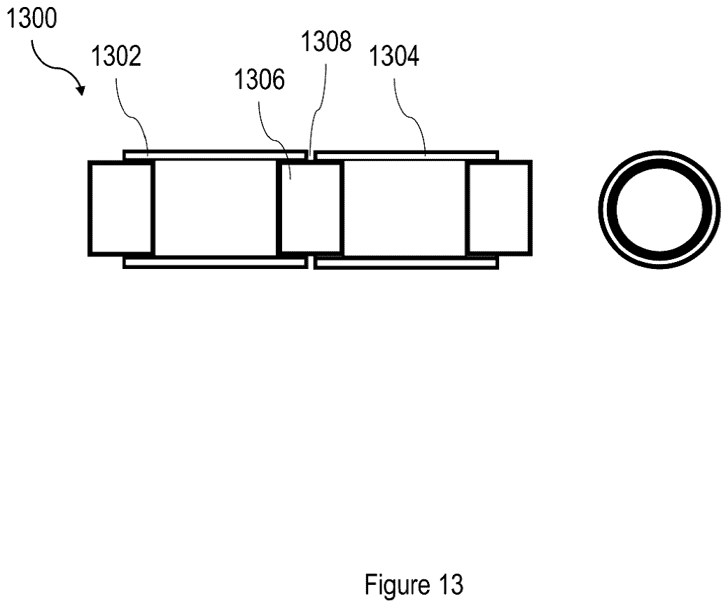

Referring now to FIG. 13 shown therein is constraining reservoir 1300 with a mid-length gas escape, according to an embodiment. The constraining reservoir 1300 may be the constraining reservoir 106 of FIG. 1. The constraining reservoir 1300 is similar to the constraining reservoir 1200 of FIG. 12. The constraining reservoir 1300 may have at least one hole punctured (not shown) on the constraining reservoir 1300 so as to allow escape of the high-pressure process gas. The constraining reservoir 1300 includes a first segment 1302 and a second segment 1304 of the tube or profile. The first segment 1302 and the second segment 1304 is connected with an electrode 1306. A gap 1308 between the electrode 1306 and the first segment 1032 and the second segment 1304. The gap 1308 allows the high pressure gas to escape the constraining reservoir 1300. The gap 1308 allows gas to travel a shorter length than the total length of the constraining reservoir 1300 to exit the constraining reservoir 1300.

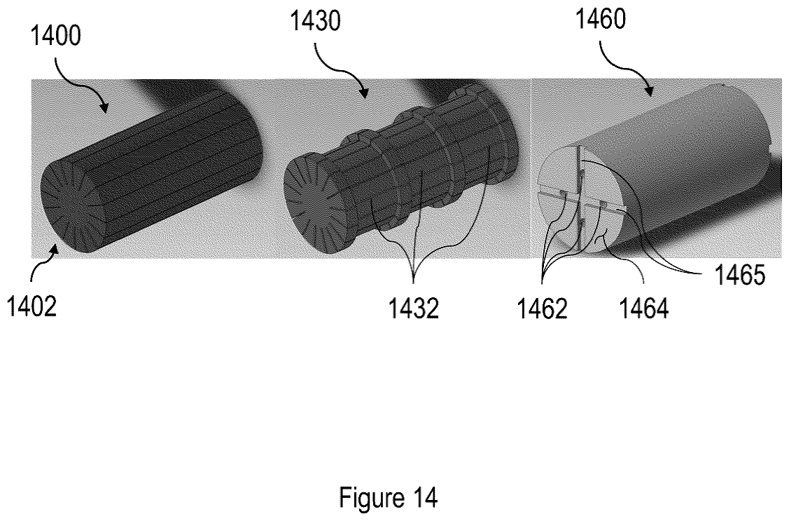

Referring now to FIG. 14, shown therein are diagrams of various electrodes 1400, 1430, and 1460 for the constraining reservoirs. The electrodes may be the electrodes 110 of FIG. 1, 308 of FIG. 3, 408 of FIGS. 4, 1216 and 1218 of FIG. 12 and 1306 of FIG. 13.

The electrode may be solid cylindrical graphite with an outer diameter (OD) that is smaller than the inner diameter (ID) of the constraining reservoir. The difference in the electrode OD and the constraining reservoir ID forms the gap of the gas escape of FIGS. 12 and 13. The electrode 1400, 1430 and 1460 may be further grooved electrodes that provide process gas escape routes particularly for closed-form containing reservoirs and longitudinally split reservoirs. In an embodiment, the electrode 1400 is cylindrical graphite electrode and has more than one radial groove 1402 cut longitudinally into the electrode 1400. In an embodiment the electrode has a 7.5 cm OD, it is more than 4 cm long, and it has 16 grooves with a groove width that is similar to the feedstock grain size.

In a further embodiment, the neck electrode 1430 is similar to the electrode 1400 but also has at least one neck 1432 wherein the neck OD is less than the main OD cut into the electrode. The neck allows the high-pressure gas to escape the reservoir and expand into space between the neck and the constraining reservoir. The neck electrode 1430 improvement can be made on a solid cylinder electrode or on a grooved cylinder electrode 1400. In an embodiment the grooved electrode has a 7.5 cm OD and a neck diameter that is between 5 and 15 percent from the main OD.

In a further embodiment, an electrode 1460 with holes 1462 (drilled electrodes) provides a process gas escape via pass through holes 1462. The holes 1462 span the length of the electrode. The end electrode faces 1464 of the electrode 1460 include venting grooves 1465 to allow gas escape at the interface between the graphite electrode 1460 and a brass electrode (not shown) that interfaces and/or pushes the graphite electrode 1460. The electrodes 1400, 1430, and 1460 may be oval, square, or rectangular, or any other shape to match the cross-section of the reservoir.

In an embodiment the closed round tube is quartz tube, and the electrodes are solid, grooved, necked, or drilled graphite electrodes. In an embodiment the quartz tube has a 7.5 cm inner diameter, in another the inner diameter is 11.5 cm, in another it is 15 cm, in another it is 40 cm and yet in another the diameter is 50 cm. In an embodiment the quartz tube has wall thickness from 2 to 5 mm.

In an embodiment the round tube is a concrete tube. The electrodes may be solid, grooved, necked, or drilled graphite electrodes. The concrete tube may be closed form or longitudinally split tube. The concrete tube may be made from normal strength or high strength concrete mix in the range from 2500 to 5000 Psi compressive strength. The concrete mix for the concrete tube may incorporate Portland cement, aggregates, high temperature additives, high strength, and high thermal conductivity additives. In an embodiment the concrete tube may incorporate rebar, mesh, or wire reinforcement components to improve the durability of the concrete tube. In an embodiment the concrete tube may incorporate graphene, TG graphene, or carbon nanotubes (CNTs) as additives that increase the compressive strength and the high thermal conductivity. In an embodiment the concrete tube has 7.5 cm to 50 cm inner diameter and wall thickness from 3 to 15 cm.

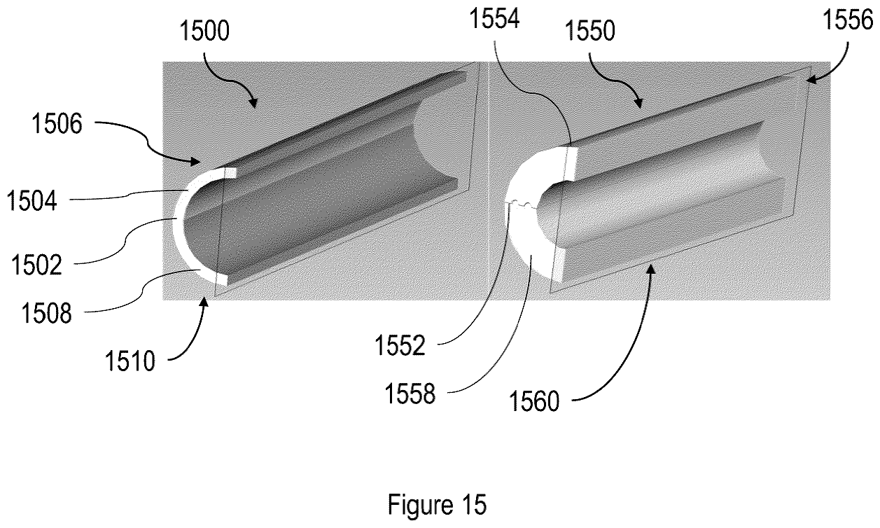

Referring now to FIG. 15, shown therein are cross-sectional diagrams of concrete constraining reservoirs 1500 and 1550. The constraining reservoirs 1500 and 1550 are longitudinally split tubes.

The constraining reservoir 1500 includes a flat interface 1502 where a first wall 1504 of a first segment 1506 interfaces with a second wall 1508 of a second segment 1510. When the full tube 1500 is assembled the half tubes 1506 and 1510 connect with a flat surface 1502. This assembly allows high pressure gas to escape from the flat gap at the interface 1502. This assembly may also allow some feedstock grains to escape.

The constraining reservoir 1550 includes a serpentine interface 1552 where a first wall 1554 of a first segment 1556 interfaces with a second wall 1558 of a second segment 1560. When the full tube 1550 is assembled the half tubes 1556 and 1560 connect with a serpentine surface 1552. This assembly allows high pressure gas to escape from the flat gap at the interface 1552. This serpentine interface may prevent feedstock grains from escape over the flat interface.

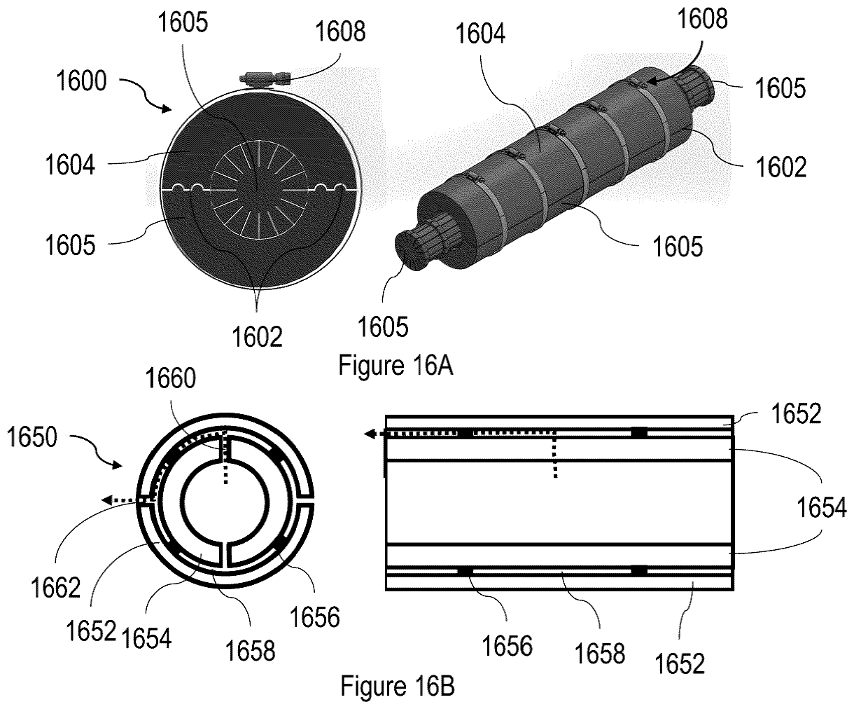

Referring now to FIG. 16A, a diagram of an assembly of a concrete constraining reservoir 1600 with grooved graphite electrodes and clamps, in accordance with an embodiment. The constraining reservoir 1600 is a longitudinally split tube. The interfaces 1602 of a first segment 1604 and a second segment 1605 are serpentines interfaces 1602. The electrodes 1606 are necked and grooved graphite electrodes. The assembly 1600 is being held by several metal hose clamps 1608. Alternatively, the assembly 1600 can be clamped using a spring-based mechanism that can be unclamped with a single motion and can be automated.

Referring now to FIG. 16B, shown therein is a diagram of a constraining reservoir 1650 of a concrete tube 1654 with a steel tube clamp 1652. The constraining reservoir 1650 includes a reusable metal, steel, or a stainless-steel tube liner 1652 on the outside diameter of a concrete tube 1654. The concrete tube 1654 with thin walls thickness from 3 to 15 cm and a large mass may take a long time to cool down. Active cooling with a heat exchanger may speed the cooling of the concrete tube 1654 or reservoirs 1650 particularly when a thin wall concrete thickness is desirable. A concrete tube 1654 with thin walls can cool faster with and without active cooling. Another advantage of the thin wall concrete tube 1654 is the amount of concrete needed to make the tube and therefore the lower cost of the concrete tube per use. It is desirable to use a concrete tube anywhere from 2 to 100 times. A thin wall concrete tube 1654 used for joule heating process is more fragile with respect to the stresses produced by the high process gas. Therefore, the wall 1654 may be reinforced by reusable metal, steel or a stainless-steel tube liner 1652 on the outside diameter of the concrete tube 1654.

In an embodiment the concrete tube 1654 is a thin-wall, longitudinally split, concrete tube, with wall thickness from 1.5 to 4 cm, lined with a longitudinally split thin steel tube 1652 with wall thickness from 0.3 to 2 mm, and clamped together as a tube assembly. In one configuration a spacer 1656 is added between the concrete tube 1654 and the steel tube liner 1652. The spacer 1656 produces a gap 1658 in the assembly where the high pressure, high temperature has can escape. The orientation of the concrete tube split 1660 and the steel tube split 1662 can be aligned to zero degrees so that the process gas exists directly from the concrete tube to the environment (not shown). The concrete tube split 1660 and the steel tube split 1662 can be rotated at 90 degrees relative to each other so that the process gas has to turn around and diffuse as it travels in the gap 1658 between the concrete tube 1654 and the steel liner tube 1652.

In an embodiment the round tube 1654 is made from castable refractory cement materials. In another example the round tube 1654 is made from concrete wherein the inner walls of the tube are coated with a layer of refractory cement. In an embodiment the round tube is made from refractory cement bricks 1654 and reinforced using refractory cement materials.

The above examples of concrete and refractory cement tubes describe a round tube; however, all the disclosure teaching can apply to square or rectangular profile reservoirs.

In one configuration of the joule heating system for making graphene the constraining reservoir filled with carbon-based feedstock is exposed to the atmosphere and air can permeate the feedstock powder, grain, pellets, or chunks. The oxygen and nitrogen from the air may react with the carbon as it gets converted from carbon to graphene. For example, a feedstock in air environment may catch fire during the joule heating process due to the residual oxygen permeated within the feedstock.

In another configuration of the system for making graphene the constraining reservoir filled with carbon-based feedstock is surrounded by an enclosure where the feedstock environment can be controlled. In an embodiment, the air in the enclosure is vacuumed out so as to remove oxygen from the feedstock environment. In another example, the enclosure may be flooded with oxygen so that during the joule heating process the feedstock carbon reacts with the oxygen to introduce more oxygen defects in the graphene lattice. In another example, the enclosure may be flooded with argon or nitrogen so that during the joule heating process the feedstock carbon is in inert environment and produce less defects in the graphene lattice. Other gasses that may be introduced into the joule heating system enclosure are helium, CO, CO₂, F₂, or NH₃, but it is not limited to these gasses.

### Joule Heating Systems Examples

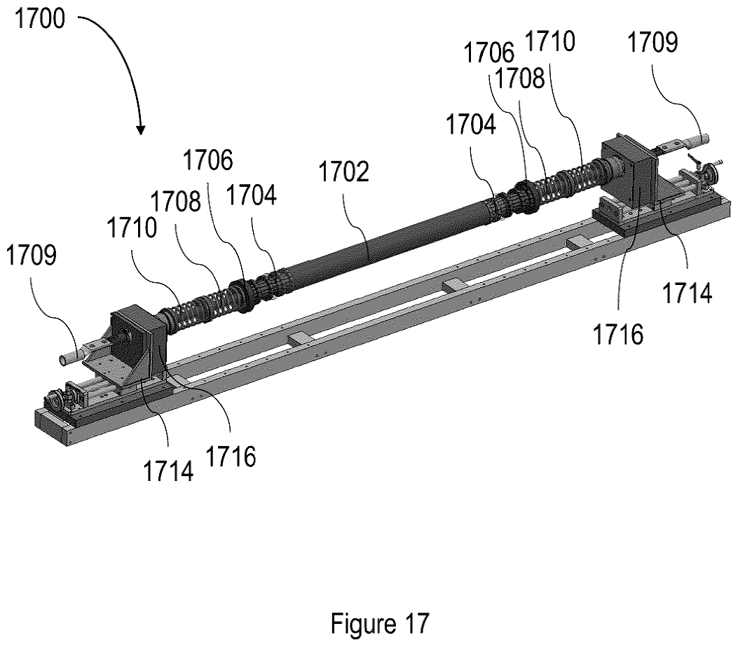

Referring now to FIG. 17 shown therein is a perspective view of a joule heating assembly 1700 with springs and linear stages, in accordance with an embodiment. The system 1700 may be the system 100 of FIG. 1. The system, for example for produces 2 kg of graphene from carbon-based feedstock. The assembly includes sub-assembly that is removed (exchanged) with each joule heating process and sub-assembly that is resident from one joule heating process to the next. The removable sub-assembly includes a quartz tube containing reservoir 1702, feedstock packed inside the quartz tube, and a set of necked and grooved cylindrical graphite electrodes 1704 containing the feedstock inside the quartz tube.

The electrodes 1704 can slide in and out of the quartz tube to stay in electrical and mechanical contact with the feedstock during compression of the feedstock before the joule heating process and during the joule heating process wherein the compression forces still act on the feedstock. The resident sub-assembly's function is to apply force and to transfer electricity from the resident to the removable sub-assembly.

In this sub-assembly the brass electrode cup 1706 holds the graphite electrode in place as the brass electrodes 1706 can move in an axial direction while they transfer electricity. The brass electrode cup 1706 is connected to a brass shaft 1708 that is connected to the power cables 1709. The electrical power is transmitted from the brass shaft 1708 to the brass disk 1706 and then to the graphite electrode 1704. The brass disk 1706 is kept under tension by springs 1710 that are compressed between the disk electrode 1706 and the electrically isolated L-bracket assembly 1714. The springs 1710 provide a linear force that is proportional to the spring constant and the spring displacement. The L-bracket assembly 1714 has a bearing 1716 in that that allows the brass shaft 1708 to slide in and out.

An optional load ring type sensor can be inserted in series with the spring and the L bracket assembly so as to measure the compression of the springs from which the forces on the feedstock can be monitored dynamically. The L-bracket assembly 1714 is connected to a linear stage that may be manual or stepper motor driven. The linear stage is connected to the fixed frame 1716. The linear stages may also be compressed air sliders. When the stage is moved forward the L-bracket assembly 1714 moves forward and compresses the springs 1710 that push the cylindrical electrodes 1704 which push the feedstock material. As the springs 1710 compress more the brass shaft 1708 and disk 1706 are able to slide with respect to the L-bracket assembly 1714. Therefore, at fixed linear stage position any changes in the feedstock compression or extension will be balanced by the spring forces moving the brass disk 1706 and shaft 1708 in and out to keep the contact to the feedstock. Configuring the assembly for other masses, up to 300 kg, requires tubes with different ID and length as described in the teachings of this disclosure. The supporting elements, such as electrodes 1704 and brass cups 1706 will have to change accordingly.

In an embodiment of the joule heating assembly 1700 for producing graphene described above, 2.1 to 2.5 kg of CPC feedstock was loaded into the tubes 1702 (which may be quartz or longitudinally split concrete). In some examples (K3-7, 8, 10, 11) it took from 56 to 85 sec for the CPC feedstock to be converted to turbostratic graphene with yields from 87 to 94%. In average, 2.3 kg CPC yielded 2.1 kg of TG (91% yield) with average process time of 71 sec. With manual sample exchange the process cycle can be as high as 5 min but with some automation the sample exchange can be done in 60 sec or less. Therefore, the total cycle time of the system in this example is 71 sec+60 sec=131 sec. If the system operates 480 min per shift (8-hour workday) and with cycle time of 2.2 min, 218 batches can be produced per one 8-hr shift. The total TG production with 218 bathes of 2.1 kg is 458 kg of TG per shift or 1.374 t of TG per day with only one joule heating system. An implementation of 10 joule flash systems running in parallel will produce 4.58 t of TG per shift or 13.74 t of TG per day with 10 stations.

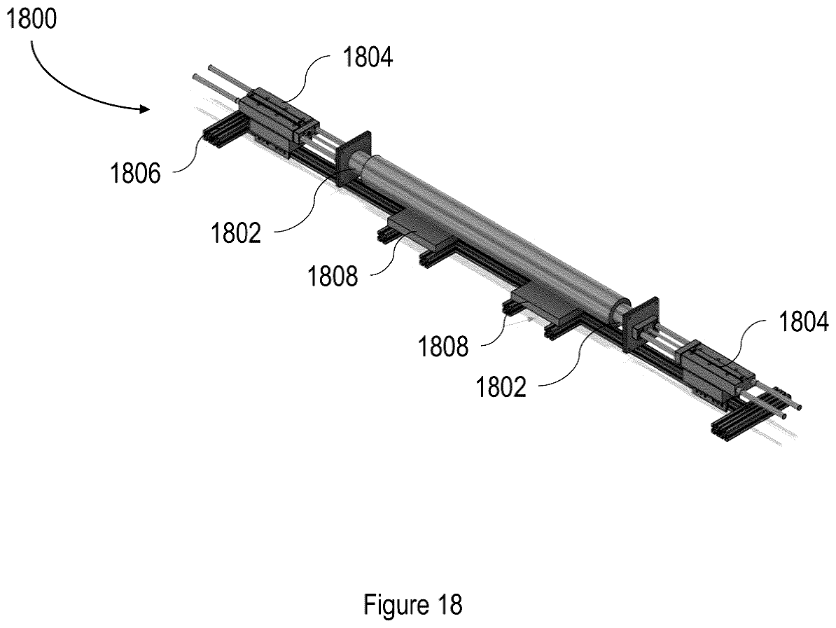

Referring now to FIG. 18 shown therein is a perspective view of a joule heating assembly 1800 with pneumatic actuators, in accordance with an embodiment. The assembly 1800 may be the system 100 of FIG. 1. The assembly may produce 1 kg of graphene from carbon-based feedstock. The assembly includes sub-assembly that is removed (exchanged) with each joule heating process and sub-assembly that is resident from one joule heating process to the next. The removable sub-assembly includes quartz tube containing reservoir, feedstock sample packed inside the quartz tube, set of cylindrical graphite electrodes that fit inside the quartz tube. The resident sub-assembly includes set of rectangular graphite electrodes 1802. The rectangular graphite electrodes 1802 pass electrical power from the resident sub-assembly to the removable sub-assembly.

The resident sub-assembly further includes pneumatic actuators 1804 that push the electrodes 1802 and the feedstock with constant pressure. The resident sub-assembly also includes aluminum frame 1806 that holds the pneumatic actuators 1804 and refractory brick support 1808 so that the quartz tube does not transfer heat to the frame 1806. The pneumatic actuators 1804 can apply constant force independent of the displacement. The pneumatic actuators 1804 can hold nearly fixed pneumatic pressure even as the pneumatic head moves and the pneumatic piston volume changes. The constant force is more advantages when the feedstock has low density and changes its volume dramatically during the joule heating process.

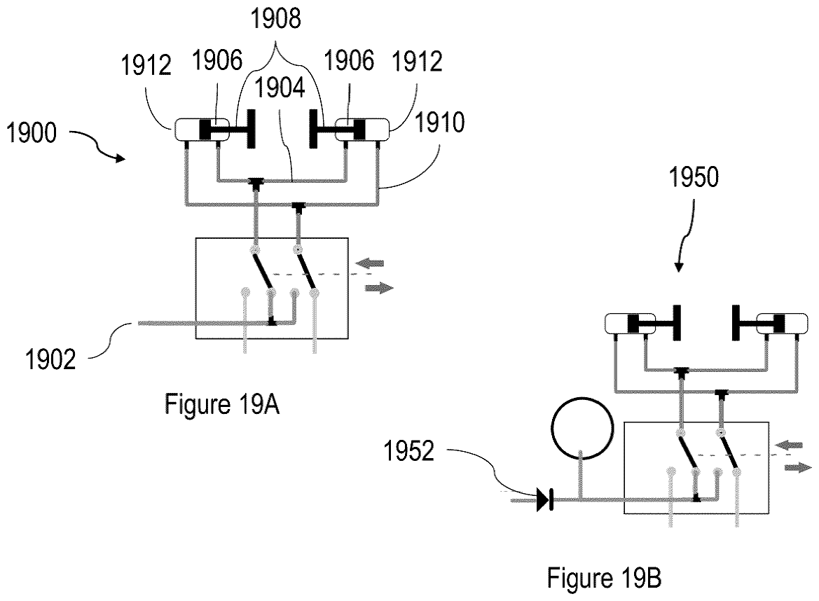

Referring now to FIG. 19 shown therein is an operational diagram of the pneumatic actuators 1900 from the Joule Heating Assembly with fixed pressure compressed air 1902 according to an embodiment. The actuators 1900 may be the actuators 1804 of FIG. 18. The compressed air 1902 may be from a compressor. It is desirable that the compressor has 10× the volume than the pneumatic system (pistons, lines, and switches). In this example when the pneumatic system is set to pressurize the push out line 1904. The pressure in the inner chamber 1906 of the piston moves the pistons 1908 to open. The push in line 1910 is open to atmosphere to let any compressed gas out. When the pneumatic system is set to pressurize the push in line 1910, the pressure in the outer chamber 1912 of the piston moves the pistons to close while the push out line 1904 is open to atmosphere to let any compressed gas out. While pushing in the pistons encounter the resistance of the feedstock until the pressure in the outer chambers equal the compressor pressure. If the feedstock contracts or expands the pressure in the chambers 1906 and 1912 will slightly change but effectively provide constant force at any displacement.

Referring now to FIG. 19B shown therein is an operational diagram of the pneumatic actuators 1950 from the Joule Heating Assembly with variable pressure compressed air, according to an embodiment. The system 1950 is similar to the system 1900 of FIG. 19A. The system 1950 further includes a check valve 1952 to provide additional force to the sample if the sample expands while providing a constant force to the sample if the sample contracts. This additional force beneficially provides confinement to a sample with high volume expansion or contraction which benefit the arc suppression.

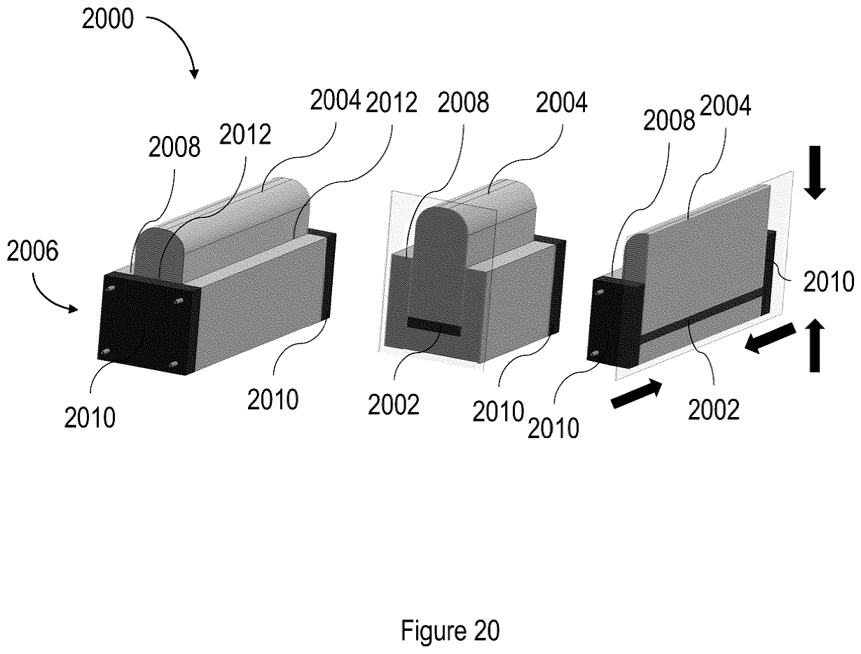

Referring now to FIG. 20, shown therein is a diagram of a joule heating assembly 2000 with perpendicular electrical and compression directions, in accordance with an embodiment. The assembly 2000 may be the system 100 of FIG. 1. The assembly 2000 compress the feedstock 2002 without springs or linear stages.

The assembly 2000 further includes a constraining reservoir 2006. The constraining reservoir 2006 includes a U-shaped trough 2008. The U-shaped trough 2008 is open at each end. A rectangular electrode 2010 is bolted on each end of the trough 2008. The constraining reservoir 2006 further includes a top weight piece 2004 for providing the compression force. The top weight 2004 is not fixed. The volume of the constraining reservoir 2006 depends on the height of the top weight 2004 with respect to the trough 2008. In an embodiment, the electrodes 2010 do not enter the cavity of the rectangular reservoir. Rather the electrodes 2010 block the feedstock 2002 from exiting the trough 2008. Alternatively, the electrodes 2010 may fit inside the cavity of the trough 2008 but do not move during the feedstock 2002 compression (not shown).

The gas escape 2012 is along a lateral gap between the top weight 2004 and the trough 2008. Gas may also escape through the gap between the sides of the top weight 2004 and the rectangular electrodes 2010.

In an embodiment of this design the top weight 2004 and the U-shaped trough 2008 are made from concrete and the rectangular electrode are made from graphite. Alternatively, the top weight 2004 and the U-shaped trough 2008 are made from refractory cement.

The compression of the carbon-based feedstock grain 2002 is perpendicular to the direction of the set of electrodes on opposing ends of the reservoir through which electrical power is applied. This is similar to the compression of FIG. 4. In an embodiment the width and the length of the trough 2008 are fixed and the height of the confining reservoir 2006 depends on the mass of the feedstock and its density. The top weight 2004 compresses the feedstock before and during the joule heating process. The top weight part 2004 can be sliced in the cross-section cut direction and made of multiple parts (not in the figure). In addition, the top weight 2004 can be compressed into the trough 2008 with help of hose clamps, a spring system that pushes the top weight, pneumatic pistons that push the top weight, or a hydraulic press that pushes the top weight until a desired bulk resistance of the feedstock is achieved. The compression force of the top weight 2004 may be kept in place during the joule heating process.

A continuous version of a joule heating assembly where the electrodes that apply power are in perpendicular configuration to the carbon feedstock compression direction is disclosed in PCT/CA2020/051565, FIGS. 4, 5, 8 and 10, which is herby incorporated as reference. The material in the confining reservoir is moved in continuous manner by an extruder screw. The disclosure in FIG. 20 solves the problem of materials for the confining reservoir from PCT/CA2020/051565 by using concrete and refractory cement materials.

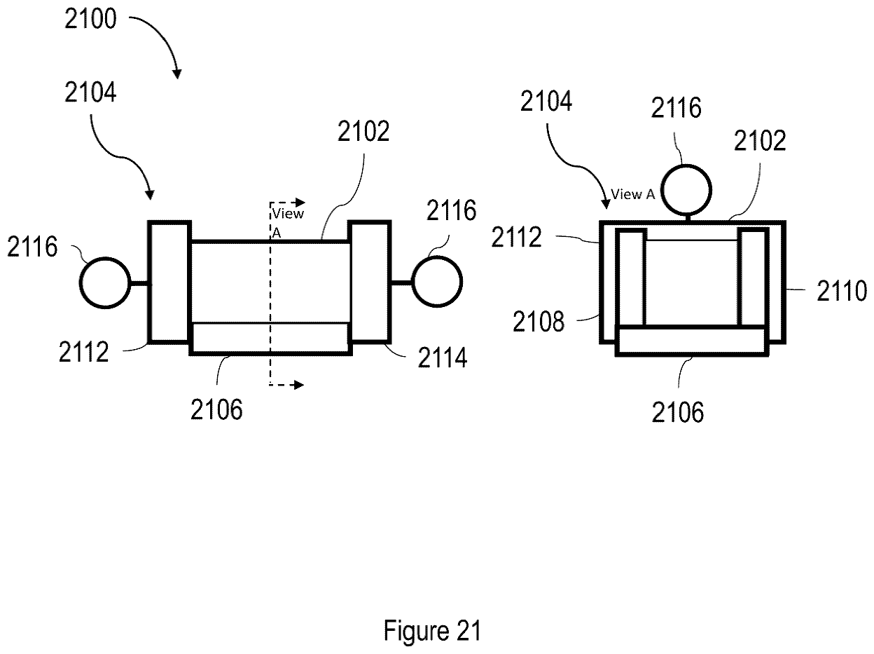

Referring to FIG. 21 shown therein are block diagrams of a System for Large Scale Joule Heat Conversion of Carbon to Graphene Without Feedstock Compression during a joule heating process during which carbon-based feedstock is converted to graphene. The feedstock 2102 is loaded into a constraining reservoir 2104. The constraining reservoir 2104 defines a rectangular space constrained by one bottom base 2106, two opposing reservoir walls 2108 and 2110 and two graphite electrodes 2112 and 2114.

The mass of the feedstock 2102 itself keeps the feedstock 2102 electrically connected to each other without the need for external compression force. The feedstock 2102 may be leveled and/or compressed so as to have relatively uniform cross section. The AC power 2116 is connected to the graphite electrodes 2112 and 2114. When power is applied across the electrodes 2112 and 2114, the carbon-based feedstock 2102 between the electrodes 2112 and 2114 is joule heated and is converted to graphene. One advantage of this system is that intense radiation heat and gas pressures that are generated during the joule heating process can easily escape the feedstock 2102. The bottom corners between the reservoir bottom 2106 and walls 2108 and 2110 may be rounded or have chamfer so as to enable more uniform electrical flux across the feedstock 2202 cross section profile.

In some cases, the power applied to the electrodes is a rectified AC power 1216 that produces DC output. The rectification can be single phase or three phase and it can be half-wave or full-wave rectified.

In an embodiment the bottom 2106 and walls 2108 and 2110 of the joule flashing reservoir are made from standard high alumina bricks with 70% to 90% alumina content with a typical brick size of 9×4.5×2.5 inches. The brick reservoir may be made by joining multiple bricks to extend the size of the brick reservoir. The brick reservoir may be assembled by keeping the bricks with clamping force or it can be cemented using castable refractory cement compatible with the brick material. In an embodiment the walls and the bottom are made from 1 to 10 bricks long and 1 to 5 brick high and 1 to 5 bricks wide.

In another example, the brick reservoir may be made from at least one of the group comprising: fire clay-bricks, high alumina bricks, alumina bubble bricks, alumina spinel bricks, AZS bricks, ZrO₂ bricks, corundum bricks, insulating fire bricks, magnesite bricks, mullite bricks, silica bricks, silicon carbide bricks, silicon nitride/silicon carbide bricks, and zircon bricks. The brick reservoir may also include castable refractory materials from the above list to join the bricks in a brick reservoir. In some cases, the castable refractory materials can be molded into variety of shapes (half tube, rectangle, trapezoid, tub shaped, etc.,) of refractory-based reservoirs for joule heating of the feedstock 2102.

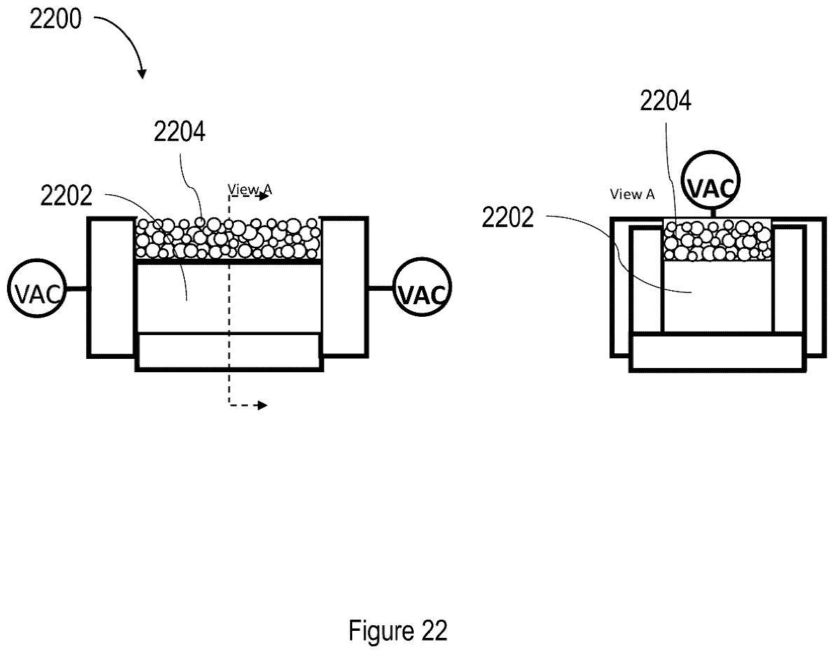

Referring now to FIG. 22, shown therein is a System 2200 for Large Scale Joule Heat Conversion of Carbon to Graphene Weighted Down and Without Feedstock Compression, in accordance with an embodiment. The system 2200 may be the system 100 of FIG. 1. The system 2200 is similar to the system 2100 of FIG. 21. For carbon-based feedstock 2202 with low density such as bio derived char (BC) feedstock chunks the mass of the feedstock 2202 may be low to keep good electrical contact between the chunks but may result in arcing or non-uniform joule heating.

The system further includes a weighting material 2204. The top of the feedstock 2202 is covered with the weighting material 2204. Weighing down the feedstock 2204 helps provide good electrical contact among the feedstock 2202 particles/chunks. The weighting material 2204 is of high-temperature resistant material. In an embodiment the weighting material 2204 may be made from quartz, ceramic, silicon carbide, magnesia-based refractories, dolomite, alumina refractories, BN, Al₃N₄, Si₃N₄ and any combination thereof.

The weighting material 2204 has enough porosity to allow gas and heat to escape the porous media. In yet another example the shape of the weighing material 2204 is irregular. This irregularity may beneficially give the weighting material additional porosity.

The weighting material may include large (at least order of magnitude larger than the feedstock particles size) pebbles. The pebbles weigh down the low-density feedstock 2202 during a joule heating process. The weighting material may include cylinders covering the top surface of the feedstock 2202 to weigh the feedstock 2202 down.

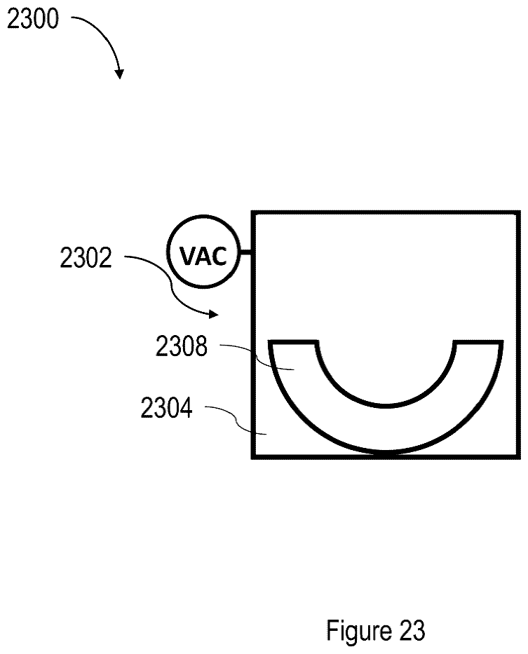

Referring now to FIG. 23, shown therein is a block diagram of a Half-Tube Based System 2300 for Large Scale Joule Heat Conversion of Carbon to Graphene Without Feedstock Compression, in accordance with an embodiment. The system 2300 is similar to the system 2200 of FIG. 22. The constraining reservoir 2302 is a half-tube shape. Two graphite electrodes 2304 and 2306 (not shown) are positioned at the open ends of the half-tube 2308. The half tube 2308 may be of quartz or concrete. The half-tube 2308 may also be made from other refractory materials described above. One advantage is that the electrical flux in the feedstock cross section is very uniform allowing for more uniform joule heating.

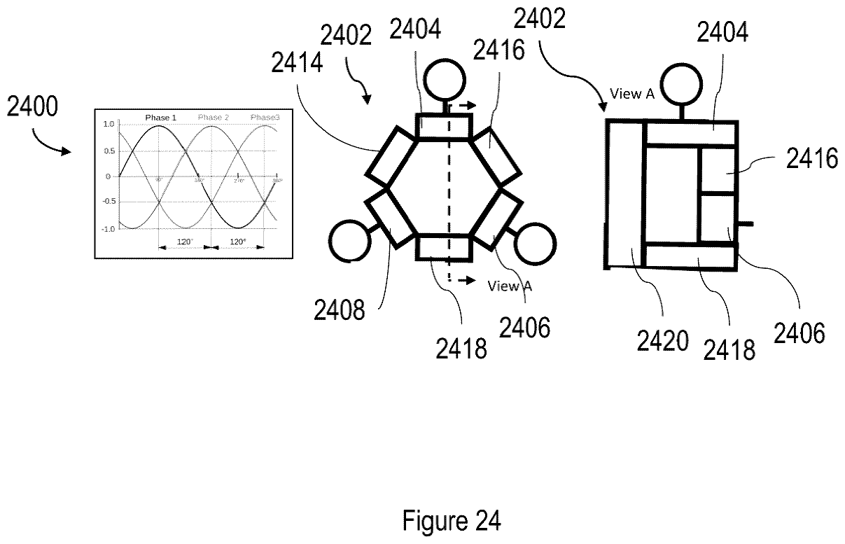

Referring now to FIG. 24, shown therein are block diagrams of a 3-Phase Delta Powered System 2400 for Large Scale Joule Heat Conversion of Carbon to Graphene Without Feedstock Compression, in accordance with an embodiment. The system 2400 may be the system 600 of FIG. 6. The system 2400 includes a constraining reservoir 2402. The constraining reservoir 2402 is hexagonal in shape when viewed from the top. Each side of the constraining reservoir is one of 3 graphite electrodes 2404, 2406, and 2408 and 3 reservoir walls 2414, 2416, and 2418. The sides alternate between electrode and wall. The constraining reservoir further includes a base 2420.

The 3-electrode system is configured to operate with a 3-wire Delta electrical power supply wherein each phase of the power supply is 120 degrees offset from each other. In this 3-phase electrical power configuration each phase is connected to a different electrode 2404, 2406, and 2408. Each phase voltage may be configured to provide from 100 to 1500 VAC RMS from Line-to-Line. In a 3-phase joule heating there are currents flowing from each electrode 2404, 2406, and 2408 to each remaining electrode in a sinusoidal manner. The currents pass through the sections of the feedstock confined by the electrodes through which the currents are flowing. At any given moment, there will be current flowing from each of the electrode sets as there is no zero current moment in the 3-phase operation. One advantage of a 3-phase joule heating system is the best utilization of the grid power where each the 3 phases are better balanced than a system operating at one phase at a time. Another advantage is the uniform joule heating of the feedstock. The feedstock reservoir 2402 may also be a cylinder with 6 segments comprising of 3 curved graphite electrode segments, 3 curved reservoir wall segments, and one base, and wherein the radius of curvature of each element needs to be same (not shown).

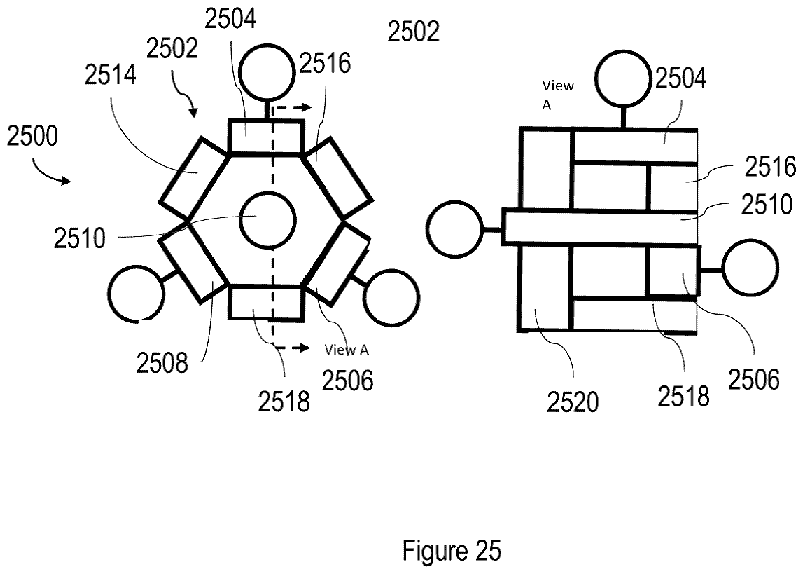

Referring now to FIG. 25, shown therein is a block diagram of a 3-Phase Wye and Delta Powered System 2500 for Large-Scale Joule Heat Conversion of Carbon to Graphene Without Feedstock Compression, in accordance with an embodiment. The system 2500 may be the system 500 of FIG. 5. The system 2500 includes a constraining reservoir 2502. The constraining reservoir 2502 is hexagonal in shape when viewed from the top. Each side of the constraining reservoir is one of 3 graphite load electrodes 2504, 2506, and 2508, a central neutral electrode 2510 and 3 reservoir walls 2514, 2516, and 2518. The sides alternate between electrode and wall.

The constraining reservoir further includes a base 2420. The base 2420 has an opening for the central electrode 2510.

The electrodes 2504, 2506, 2508, and 2510 electrodes are configured to operate with a 4 wire Wye electrical power supply and wherein each phase is 120 degrees offset from each other. Each phase voltage may be configured to provide from 100 to 1500 VAC RMS from Line-to-Neutral. In this configuration the current flow of each phase is from each of the load electrodes 2504, 2506, and 2508 phase to the Neutral electrode 2510 (the center electrode).

One advantage of this 3-phase Wye joule heating system is the best utilization of the grid power where each the 3 phases are better balanced than a system operating at one phase at time. Another advantage is the uniform joule heating of the feedstock.

The constraining reservoir 2502 may also be a cylindrical tube with 6 segments comprising of 3 curved graphite electrode segments, 1 cylindrical electrode in the center of the tube, 3 curved reservoir wall segments, and one base, and wherein the radius of curvature of each element needs to be same (not shown).

In system 2500 may be configured to provide the joule heating utilizing both the Delta electrical configuration and the Wye electrical configuration in a serial sequence. In the preheating sequence of the joule heating process the system 2500 may be configured to operate in Delta configuration until the feedstock preheats sufficiently and then the configuration is changed to Wye or vice versa. The Wye-to-Delta switching may occur by providing a switch to the neutral line (not shown).

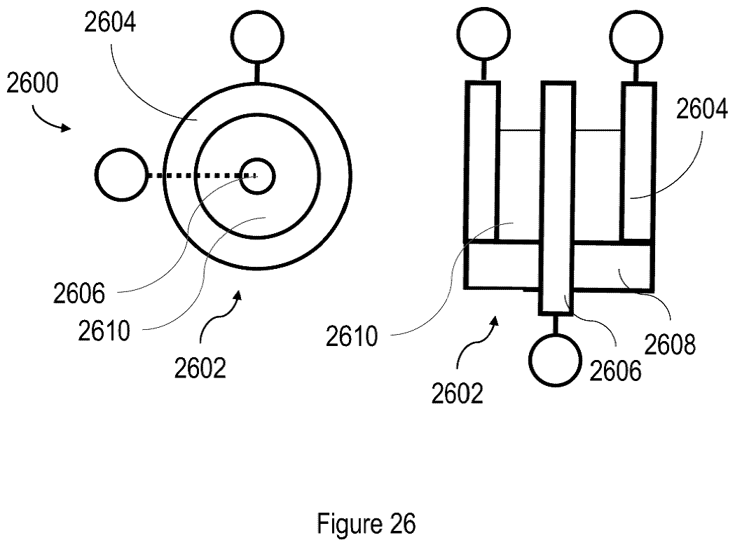

Referring now to FIG. 26, shown therein are block diagram of a Coaxial Electrodes Shaped System 2600 for Large Scale Joule Heat Conversion of Carbon to Graphene, Without Feedstock Compression, in accordance with an embodiment. The system may be the system 100 of FIG. 1. The system includes a constraint reservoir 2602. The constraining reservoir 2602 is a cylindrical tube reservoir. The constraint reservoir also includes an outer electrode 2604. The outer electrode forms the outer wall of the constraining reservoir.

The system 2600 further include and inner electrode 2606. The inner electrode 2606 is a cylinder in the middle of the constraining reservoir 2602. In an embodiment, the electrode material is graphite. The electrodes 2604 and 2606 are positioned in coaxial configuration.

The system 2600 further includes a base 2608. The base 2608 includes and an opening for the center electrode 2606 to pass through.

The feedstock 2610 fills the space between the outer electrode 2604 and the inner electrode 2606 above the bottom 2608 of the reservoir 2602. The top of the feedstock 2610 is open to the environment and without any external compression force.

The electrical connection of this system 2600 is such that the outer electrode 2604 can be connected to a single phase of a 3-phase grid power and the inner electrode 2606 is the neutral or another phase of the 3-phase grid power, or vice versa.

The advantage of this system is that the graphite electrodes also act as the reservoir wall components, reducing the need for additional wall material. Another advantage is the uniformity of the electrical field inside the reservoir resulting in a uniform joule heating process.

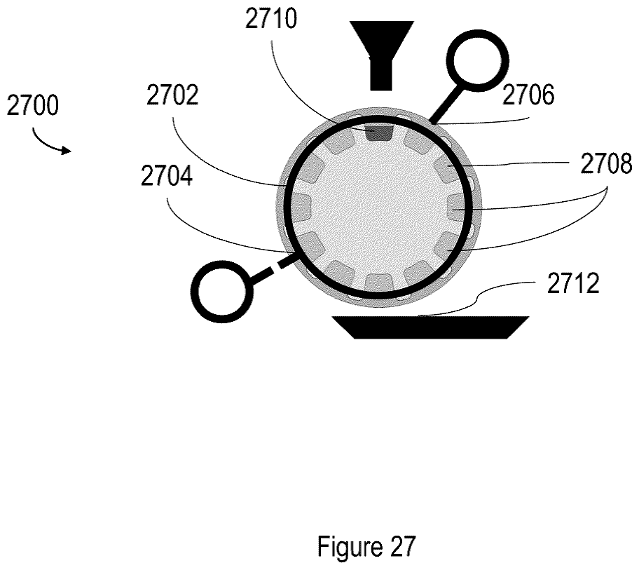

Referring now to FIG. 27, shown therein is a block diagram of a Gear Shape System 2700 for Continuous Joule Heating Process, in accordance with an embodiment. The system 2700 may be the system 100 of FIG. 1. The system 2700 includes a gear shaped reservoir 2702. The gear reservoir 2702 may be made from castable refractory materials (as listed above). The gear reservoir 2702 is rotatable to receive incoming feedstock 2710 and dispense converted feedstock 2712.

The gear reservoir 2702 is sandwiched between two electrodes 2704 and 2706. The electrodes 2704 and 2706 may be oversized in that the diameter of the electrode is greater than the outer diameter of the gear reservoir 2702. The electrodes 2704 and 2706 are round and flat in form. The electrodes 2704 and 2706 provide the power for the joule heating process.

The gear reservoir 2702 includes multiples individual reservoirs 2708. The feedstock 2710 is evenly distributed in one of the individual reservoirs 2708 of the gear reservoir 2702 at any given time.

After the process the TG product is collected as the gear 2702 rotates to a new position. The advantage of the system is the continuous processing as the gear 2702 is rotating. The idle time of each reservoir in the gear allows it to cool down before new batch is processed.

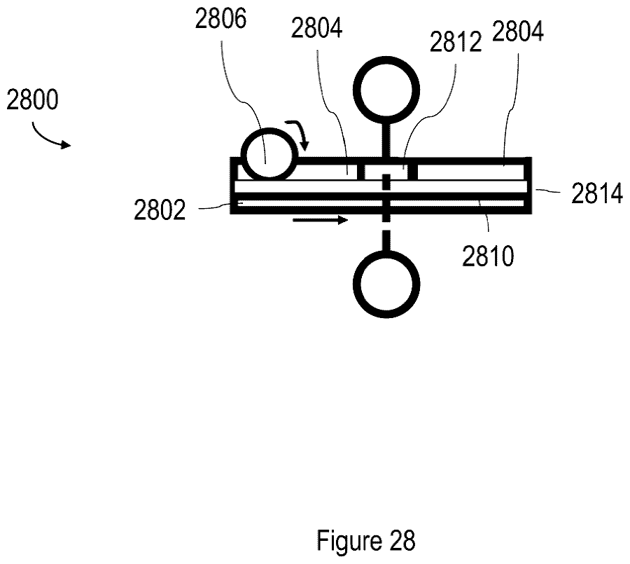

Referring now to FIG. 28, shown therein is a block diagram of a Conveyer Belt System 2800 for Continuous Joule Heating Process, in accordance with an embodiment. The system 2800 may be the system 100 of FIG. 1. The system 2800 includes a conveyer 2802. The conveyer 2802 may be made from one of the high temperature stable materials listed elsewhere in the disclosure. The conveyer further includes static walls 2804 to confine the material flow. The static walls 2804 are made from high temperature resistance material.

The system further includes a compressing roll 2806. The compressing roll 2806 is sandwiched between the static walls 2804. The compressing roll 2806 may flatten the feedstock 2810 on the conveyer belt 2802 to make the feedstock 2810 uniform. More uniform feedstock 2810 may result in a more uniform joule heating process, further resulting in more homogeneous TG fabrication.

The system further includes a graphite electrode 2812. The graphite electrode 2812 replaces the section of the static wall 2804.

In an optional process step, as the feedstock 2810 approaches the electrode, low current heats up the feedstock 2810 at low heating rate to remove volatiles from the feedstock 2810.

As the feedstock 2810 moves through the electrodes, it will reach the highest temperature of the joule heating process and convert the carbon into graphene. After the process, the feedstock 2810 can be cooled down while it is traveling on the conveyer belt 2802 to the collection location 2814. The advantage of this design is the ease in construction as well as continuous processing that increases the production throughput.

### Application Examples

The fabrication of turbostratic graphene (TG) with large mass and high fabrication rate as disclosed herein is suitable for large number of applications wherein a small percent of TG in the composite material may improve the static and dynamic strength of the composite, its thermal properties, its durability, its cyclability, its degradation resistance, its electrical properties, and its acoustic properties. In an embodiment a 0.05 to 2 percent of TG graphene may be added to improve the performance of the composite. In an embodiment the TG is added to cement, concrete, polyurethane foam, plastics, nylon rubber, tire products, asphalt, epoxy, and lubricants to improve the properties of the composite.

In an embodiment TG was added to concrete cylinders for evaluating its benefits to the cement composite. In this example, general use cement, potable water, TG, sand, and limestone 19 mm were used to prepare the concrete cylindrical specimens with dimensions 4″ by 8″. The mix-design chosen for batching the 1 m³ concrete specimens was 250 kg/m³ cement, 864 kg/m³ sand, 1130 kg/m³ stone, 167.5 kg/m³ water, 250 ml admixture per 100 kg cementitious content. The TG was speed-mixed and incorporated as dispersant-stabilized aqueous dispersion at 0.1 wt % of the cement. High-shear mixing was employed to obtain a uniform TG dispersion. The dispersion was mixed with the rest of the ingredients in a drum-type mixer during the batching. Standard practices outlined both in CSA A23.1:19/A23.2:19 and ASTM C192 were followed for making and curing the concrete specimens. The concrete was poured in three layers in the plastic molds and each layer consolidated using tamping rod. The specimens were demolded after 24 hours and transferred to lime-saturated water for curing. The 7-days cured specimens were tested for their compressive strength using Forney Automatic Compression Testing Machine. The steel caps with neoprene pads cushioning were used for capping the concrete cylinders as outlined in ASTM C 1231. The rate of loading during compressive strength test was within the range of 0.15 MPa/s to 0.35 MPa/s as outlined in ASTM C 39. Average of three specimens was taken as representative compressive strength.

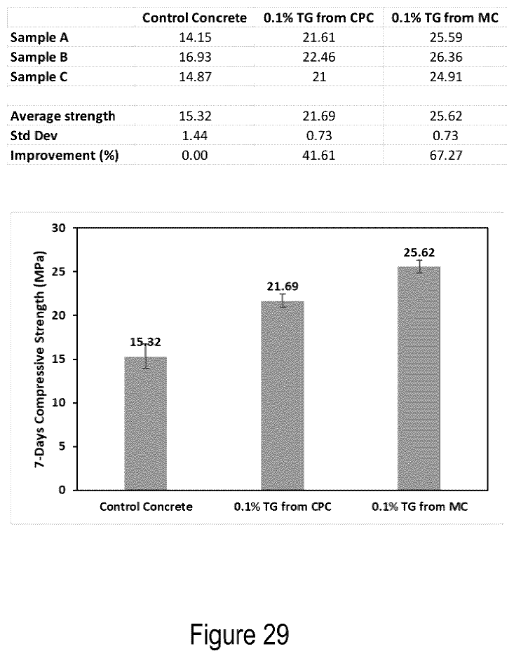

Referring now to FIG. 29, shown therein are graphs of Compressive Strength Improvement of Concrete Composite with 0.1% TG, in accordance with an embodiment. 0.1 wt % TG (from CPC) modified concrete cylinders showed a relative improvement of 41.5% in compressive strength against the control (without TG) and in another example, 0.1 wt % TG (from MC) modified concrete cylinders showed a relative improvement of 67% in compressive strength against the control (without TG)

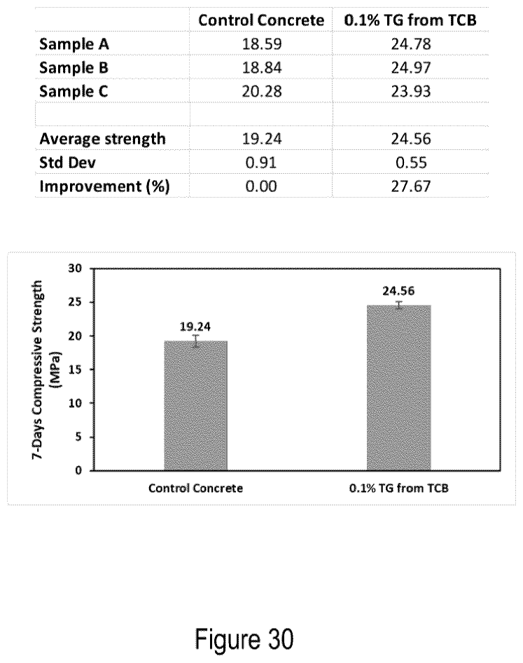

Referring now to FIG. 30, shown therein are graphs of Compressive Strength Improvement of Concrete Composite with 0.1% TG, in accordance with an embodiment. 0.1% TG, in accordance with an embodiment. In yet another example, 0.1 wt % TG (from recycled-tire carbon black) modified concrete cylinders showed a relative improvement of 28% in compressive strength against the control (without TG).

### Production Line Designs

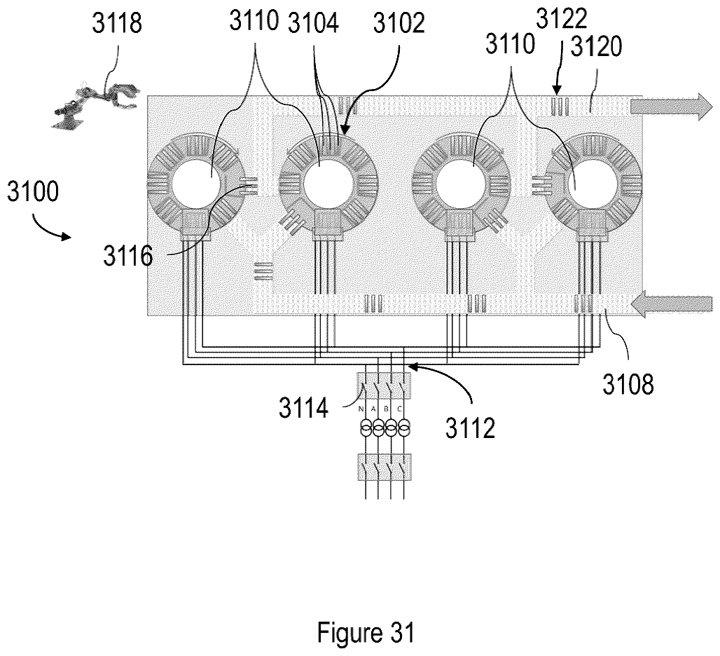

Referring now to FIG. 31, shown therein is a block diagram of a system 3100 for Continuous Production Line for Joule Heating with 3 Phase Power, in accordance with an embodiment. The system 3100 includes multiple basic joule heating cells 3102. The basic joule heating cell 3102 comprises of three constraining reservoirs 3104 (tube or rectangle, quartz or cement or refractory materials). The basic joule heating cell 3102 is loaded into a carrier 3106 (not shown). The carrier 3106 holding the basic joule heating cell 3102 is moved with a loading linear conveyer 3108 towards a rotational conveyer 3110. The system includes 4 rotational conveyers 3110. Each rotational conveyers 3110 can hold 8 separate carriers 3106 (with 3 constraining reservoirs 3104).

A 4 wire Wye output 3112 provides 3 phases. Each phase voltage is from 100 to 1500 VAC RMS from Line-to-Neutral. The system 3100 is configured to operate 3 phases concurrently, where 3 joule heating systems can be operated simultaneously. The power is applied only at one carrier 3106 at one of each rotational conveyer 3110 station. When a first rotational station 3110 is operational 3 phase power is applied to one of the carriers by joule heating 3 reservoirs in one carrier at once. In the meantime, the remaining rotational stations 3110 are being loaded. After the carrier 3106 of the first rotational station 3110 has been processed a power switch 3114 is immediately switched to the next rotational station 3110. When the power is switched to another carrier 3106 with 3 reservoirs is processed. In the meantime, the processed sample in the first rotational station 3110 is rotated by one carrier 3106. The rotation loads a new carrier 3106 and moves the processed carrier 3106 one spot to the left (clockwise) to allow it to cool. Once the carrier 3106 reaches an unloading position 3116 the processed carrier 3106 is removed and further moved with an unloading robotic arm 3118 to an unloading linear conveyer 3120. The unloading linear conveyer 3120 conveys the processed samples 3122 to a location where the graphene can be unloaded.

In a further example, production line for continuous joule heating process each reservoir comprising of 2.6 kg of CPC feedstock, and each carrier comprises of three reservoirs, where each carrier has 7.8 kg of CPC feedstock. In this example there are 2 rotational conveyers S1 and S2 that each can hold 8 separate carriers. If the production is conducted with 3-phase power where each carrier (with three reservoirs) is joule heated at once and with a yield of 90% for CPC feedstock, then with each joule heating step the tool can make 7 kg of TG. In this example, the time to produce TG from CPC in this example is 45 sec. Using the strategy of the production line 3100 of FIG. 31 with two rotational conveyers S1 and S2, right after container 1 (S1-C1) was joule heated to make 7 kg of graphene the container S2-C1 from the rotational conveyer S2 can be operated to make another 7 kg batch of graphene. Since there are no mechanical motions between these two operations the switch time can be as short as 1 sec, a time to stop the power switch at station S1 and energize the power switch at station S2. Therefore, the cycle total cycle time of the system in this example is 45 sec+1 sec=46 sec. While carrier S2-C1 is being operated the carrier S1-C2 is being rotated into position, while at the same time the carrier S1-C7 is being removed from the station S1 and into the linear conveyer belt and carrier S1-C8 is being loaded into the empty slot of station S1. If the system operates 420 min per shift (8-hour workday) the throughput rate of this example is 9.2 kg per minute and 3.8 mt per shift. For 3-shift operation the throughput is 11.5 mt per day. For 347 days annual operation the throughput is 4,003 mt per year. An implementation of 10 production lines running in parallel will produce 115 mt of TG per day and 40,000 mt per year.

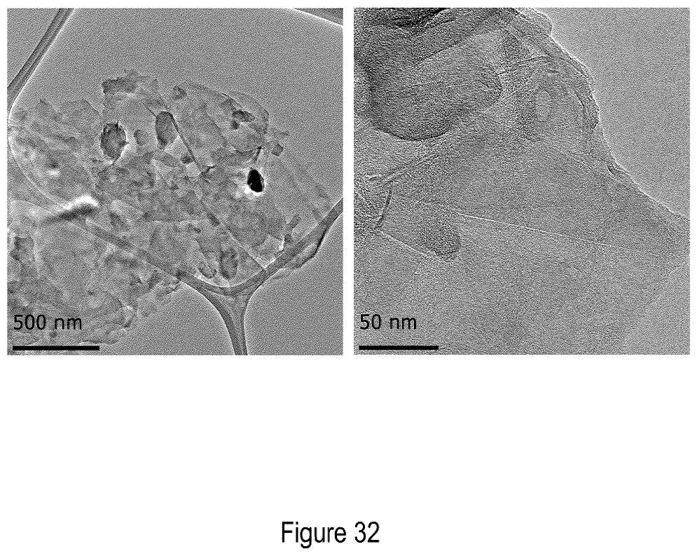

Referring now to FIG. 32, shown therein is a transmission electron microscopy (TEM) image of a flake-like graphene (TG) at various resolutions, in accordance with an embodiment. The flake like graphene (TG) shown may be the flake like graphene (TG) further described above.

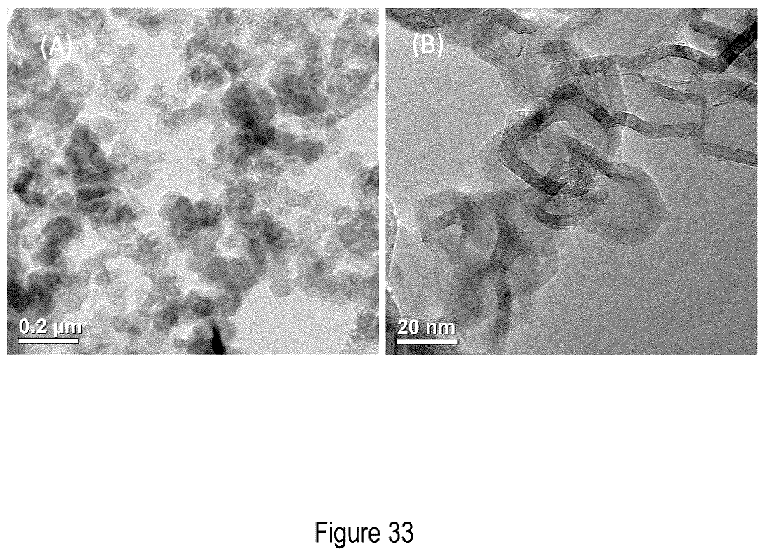

Referring now to FIG. 33, shown therein is a TEM image of a polyhedral graphene (PG) nanoparticles at various resolutions, in accordance with an embodiment. The polyhedral graphene (PG) nanoparticles shown may be the polyhedral graphene (PG) nanoparticles further described above.

Although the disclosed materials, apparatus, methods, and systems for industrial production of graphene has been disclosed in detail, the disclosed materials, apparatus, methods, and systems can be used for industrial production or refinement of other 2D and 1 D materials, such as:
(i) 1D carbon, single and multiwalled carbon nanotubes, carbon nanoribbons;
(ii) non-graphene 2D materials: molybdenum disulfide (MoS2), tungsten disulfide (WS2), boron nitride (BN), boron-carbon-nitrogen a.k.a. borocarbonitride (BxCyNz);
(iii) organic materials: fluorinated nanodiamond, fluorinated turbostratic graphene, fluorinated concentric carbon, heteroatom-doped graphene (B-doped, N-doped, O-doped, P-doped, S-doped, B- and N-doped, B- N- S-doped);
(iv) carbide synthesis by the joule heating process: titanium carbide (TiC), zirconium carbide (ZrC), hafnium carbide (HfC), vanadium carbide (VC), tantalum carbide (TaC), chromium carbide (Cr2C3), molybdenum carbide (MoC), tungsten carbide (W2C), boron carbide (B4C), silicon carbide (SiC);
(v) material recovered by the joule heating process: rhodium, palladium, silver, gold, cobalt, and various rare earth elements (Sc, Y, La, Ce, Pr, Nd, Sm, Eu, Gd, Tb, Dy, Ho, Er, Tm, Yb, Lu); (v) material removed by the joule heating process: chromium, arsenic, cadmium, mercury, lead;
(vi) other materials exposed the joule heating process: aluminum oxide (Al2O3) phase change to corundum nanoparticles, graphite anode battery regeneration, cathode battery regeneration, anode, and cathode battery materials recycling.

While the above description provides examples of one or more apparatus, methods, or systems, it will be appreciated that other apparatus, methods, or systems may be within the scope of the claims as interpreted by one of skill in the art.

1. A device for conversion of at least one feedstock to a resultant material having a higher degree of crystallinity than the feedstock, the device comprising:
a constraining reservoir configured to constrain the feedstock, wherein the feedstock acts as a resistive electrical load, and wherein the feedstock comprises a mass of at least 0.1 Kg;
a plurality of electrodes configured to transmit an electrical current through the feedstock to joule heat the feedstock;
a compression system configured to compress the feedstock with a compression force to adjust feedstock electrical resistance;
an alternating current (AC) power source for providing AC electrical current to the electrodes; and
at least one electrical controller configured to control the electrical current delivered to the feedstock.

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. (canceled)

105. (canceled)

106. (canceled)

107. The device of claim 1, wherein the constraining reservoir is configured in one or more of a tube, a half tube, a hollow rectangular prism, a hollow half rectangular prism, a hollow hexagonal prism, and a gear, is composed of one or more of quartz, ceramic, cement, concrete, silicon carbide, magnesium-based refractories, magnesia-carbon, dead-burned magnesite —MgO, magnesite-chrome, magnesia-alumina spinel, dolomite, dead-burned dolomite, resin bonded dolomite, aluminum-based refractories, alumina-magnesia-graphite, fireclay refractory having hydrated aluminum silicates, high alumina refractories, and phosphate bonded high alumina and comprises a gas escape configured to allow gas produced during the conversion to escape the constraining reservoir and wherein the gas escape comprises at least one gap in the constraining structure, the gap comprising one or more of a gap at a first end of the containing reservoir, a gap at a second end of the containing reservoir, at least one groove of the electrodes, a longitudinal split in the containing reservoir wherein the longitudinal split divides the containing reservoir into a plurality of sections, a cross-sectional split in the containing reservoir wherein the cross sectional split divides the containing reservoir into a plurality of sections, a hole in the containing reservoir, and a gap between a first layer of the containing reservoir and a second layer of the containing reservoir.

108. The device of claim 1, further comprising at least one electrical switch configured to control the flow of electrical current to the plurality of electrodes loads via power lines configured to operate in one or more of a Wye configuration and a Delta configuration and a reactive component configured to add one or more of impedance and phase offset and wherein the reactive component comprises one or more of an inductor and a capacitor and wherein the AC power source comprises one or more of a grid power supply, an industrial generator, a pure AC power source and a rectified AC power source and wherein the electrodes comprise one or more of solid, grooved, necked, and drilled graphite electrodes.

109. The device of claim 1, wherein the compression assembly comprises one or more of, a spring, a clamp, a pneumatic actuator, free weight, and a compressing roll and wherein the electrodes are configured to move along the confines of the constraining structure based on feedstock volume changes.

110. The device claim 1 further comprising a first switch corresponding to a first load and a second switch corresponding to a second load, wherein the first switch and second switch are configured to be operated to engage electric current in the corresponding load.

111. The device of claim 1, wherein the AC power source further comprises one or more of a DC converter drive and a variable frequency drive for regulating the power applied by the AC power source.

112. A method for conversion of at least one feedstock to a resultant material having a higher degree of crystallinity than the feedstock, the method comprising:
filling a constraining reservoir with the feedstock comprising a mass of at least 0.1 Kg to form a resistive load;
compressing the feedstock with a compression force to adjust feedstock electrical resistance;
conductively connecting the feedstock within the constraining reservoir to an alternating current (AC) power source; and
applying the electrical power to the resistive load until a limit is reached, wherein the limit indicates that sufficient energy and power has been applied to the feedstock by the applied electric power to convert the feedstock into the resultant material.

113. The method of claim 112, further comprising:
regulating, by at least one electrical switch, the flow of electrical current to the resistive load; and
adding one or more of impedance and phase offset by a reactive component comprising one or more of an inductor and a capacitor.

114. The method of claim 112, further comprising leaving the compression force to act during the conversion, the compression applied along one or more of the direction which the electrical current is applied and perpendicular to the direction which the electrical current is applied.

115. The method of claim 112, further comprising:
operating a first switch corresponding to a first load and a second switch corresponding to a second load such that, when a switch is operated, electric current is engaged in the corresponding load, the operation of the switches being one or more of concurrently and consecutively; and
pausing between consecutive switch operations.

116. The method of claim 112, wherein applying the electrical current further comprises:
providing a first joule heating phase to a first batch of the feedstock heated to create a second batch of feedstock;
providing a second joule heating phase to the second batch of feedstock; and
varying the power applied by varying one or more of a current and a voltage of the switch wherein the power applied in first joule heating phase is different from the power applied in the second joule heating phase.

117. The method of claim 112, wherein the limit is based on one or more of a cumulative energy deposited to the feedstock, a time of running current to the feedstock, a maximum power applied to the feedstock, a feedstock resistance, a temperature, a max pressure in the constraining reservoir, a max force to the constraining reservoir, a low feedstock resistance condition, a max feedstock temperature, a max current to the feedstock, a max power to the feedstock, a max I2*t (Amp2*time) of the power lines, a max power line temperature, a max conduit temperature of a conduit, and max relay temperature of the switch.

118. The method of claim 112, further comprising loading and unloading the constraining reservoir by at least one conveyer and adding the resultant product to one or more of cement, concrete, polyurethane foam, plastic, nylon, rubber, tire products, asphalt, epoxy and lubricant.

119. A resultant material produced by conversion of at least one feedstock to a resultant material having a higher degree of crystallinity than the feedstock, the conversion comprising:
filling a constraining reservoir with the feedstock comprising a mass of at least 0.1 Kg to form a resistive load;
compressing the feedstock via a compression force up to adjust feedstock electrical resistance;
conductively connecting the feedstock within the constraining reservoir to an alternating current (AC) power source; and
applying the electrical power to the resistive load until a limit is reached, wherein the limit indicates that sufficient energy and power has been applied to the feedstock by the applied electric power to convert the feedstock into the resultant material.

120. The material of claim 119, wherein:
the feedstock comprises carbon derived from one or more of hydrogen production process that includes the production of turquoise hydrogen from methane, metallurgical coke, anthracite coal, green petroleum coke, calcinated petroleum coke, recycled-tire carbon black, carbon black, char, bio char, wood char, plant char, ground coffee, coffee char, plastic, plastic char, plastic ash, polypropylene, polyethylene, polyurethane, and Styrofoam;
a morphology of the feedstock is one or more of super fine grain or powder, micro fine grain or powder, very fine grain, fine grain, coarse grain, pellets, medium chunks, chips, and MetCoke breeze, and at least one pill; and
the resultant material comprises any one or more of graphene, 1 D and 2D carbon, single walled carbon nanotubes, multiwalled carbon nanotubes, carbon nanoribbons, molybdenum disulfide, tungsten disulfide, boron nitride, borocarbonitride, fluorinated nanodiamond, fluorinated turbostratic graphene, fluorinated concentric carbon, heteroatom-doped graphene, titanium carbide, zirconium carbide, molybdenum carbide, tungsten carbide, boron carbide, silicon carbide, niobium carbide, rhodium, palladium, silver, gold, cobalt, rare earth elements, corundum nanoparticles, graphite anode battery materials, and cathode battery materials.

121. The material of claim 119, wherein the feedstock further comprises at least one secondary material, wherein the secondary material is one or more of sacrificial, a catalyst, or a reactant and wherein the secondary material comprises one or more of water, ground coffee, corn starch, pine bark, polyethylene microwax, wax, chemplex 690, cellulose, naptenic oil, asphaltenes, gilsonite, water, Carboxy Methyl Cellulose (CMC), lignan, lignin, sodium lignosulfonate, calcium lignosulfonate, developmental sodium lignin, desugared calcium lignosulfonate, ammonium lignon sulfonate, calcium lignin, brewers condensed solubles, de-sugarized beet molasses, calcinated petroleum coke, tire carbon black, carbon black, metallurgical coke, turbostratic graphene, and carbon nanotubes, Fe, Cu, Al, transition group metals, main group metals, TiO2, Al₂O₃, SiO2, oxides, NaCl, KCl, MgCl2, CaCO3, CuSO4, metal salt, KOH, NaOH, bases, Pt, Pd, Ru, Au, Ir, Rh, Co, Fe, Cu, Ni, Zn, Bi, Pt(acac)2, AuCl3, AgNO3, metal precursor, TiO2, Al₂O₃, SiO2, iron acetate, iron chloride, iron acetylacetonate, metal salt, iron oxide, cobalt oxide, transition metal oxide, iron hydroxide, nickel hydroxide, transition metal hydroxide, silicon, silicon oxide, and SiOx-based anode material.

122. The material of claim 119, wherein the conversion further comprises:
operating a first switch corresponding to a first load and a second switch corresponding to a second load such that, when a switch is operated, electric current is engaged in the corresponding load, the operation of the switches being one or more of concurrently and consecutively; and
pausing between consecutive switch operations.

123. The material of claim 119, wherein applying the electrical current further comprises:
providing a first joule heating phase to a first batch of the feedstock heated to create a second batch of feedstock;
providing a second joule heating phase to the second batch of feedstock;
varying the power applied by varying one or more of a current and a voltage of the switch; and
regulating the power applied.

124. The material of claim 119, wherein the limit is based on one or more of a cumulative energy deposited to the feedstock, a time of running current to the feedstock, a maximum power applied to the feedstock, a feedstock resistance, a temperature, a max pressure in the constraining reservoir, a max force to the constraining reservoir, a low feedstock resistance condition, a max feedstock temperature, a max current to the feedstock, a max power to the feedstock, a max I2*t (Amp2*time) of the power lines, a max power line temperature, a max conduit temperature of a conduit, and max relay temperature of the switch.

125. The material of claim 119, wherein the constraining reservoir further comprises a gas escape configured to allow gas produced during the conversion to escape the constraining reservoir.
